(19) United States
(12) Patent Application Publication
(10) Pub. No.: US 2003/0111683 A1
(43) Pub. Date: Jun. 19, 2003

(54) Method of fabricating transistor

(75) Inventor: Kenji Yoshiyama, Hyogo (JP)

Correspondence Address: McDERMOTT, WILL & EMERY, 600 13th Street, N.W., Washington, DC, 20005-3096, US

(73) Assignee: Mitsubishi Denki Kabushiki Kaisha

(21) Appl. No.: 10/201,201

(22) Filed: Jul. 24, 2002

(30) Foreign Application Priority Data
Dec. 14, 2001 (JP) 2001-381291(P)

(51) Int. Cl. H01L 27/108

(52) U.S. Cl. 257/302

(57) ABSTRACT

In a resist pattern for an element formation region, when an orientation flat angle which an angle to the axis perpendicular to the orientation flat of a semiconductor substrate is 270 degrees, a distance between one side face of a gate electrode to an end portion of the resist pattern and the film thickness “t” of the resist pattern are adjusted so that ions of boron are not implanted into an region of semiconductor substrate directly under the gate electrode. In the resist pattern for another element formation region, when the orientation flat angle is 90 degrees and 270 degrees, the distance between each of side faces of the gate electrode to an end portion of the resist pattern and the film thickness “t” of the resist pattern are adjusted so that ions of boron are implanted into the region of semiconductor substrate directly under the gate electrode.

### BACKGROUND OF THE INVENTION

1. Field of the Invention

The present invention relates to a method of fabricating a transistor and, more particularly to a method of fabricating transistors of different kinds.

2. Description of the Background Art

In recent years, a system LSI (Large Scale Integrated Circuit) in which a memory is provided with the function of a logic or the like is being actively developed. In such a system LSI, transistors of different kinds are formed in the same chip. A method of forming each of transistors of six different kinds will be described.

First, a first transistor will be described. As shown in FIGS. 38 and 39, a trench isolation oxide film 103 for providing an element formation region is formed in the main surface of a semiconductor substrate 101. In the element formation region, for example, by implanting p-type impurity ions, a p-type well 102 is formed. A gate electrode 105 is formed on the surface of semiconductor substrate 101 via a gate insulating film 104.

As shown in FIGS. 40 and 41, a resist pattern 106 is formed on semiconductor substrate 101. By using resist pattern 106 as a mask, arsenic is implanted into the region of semiconductor substrate 101. At this time, an implantation angle to the axis, as a reference, perpendicular to the surface of semiconductor substrate 101 is 0 degrees, implantation energy is 5 KeV, and a dose is 5×10¹⁴/cm².

Implantation is carried out in four steps of orientation flat angles of 0 degrees, 90 degrees, 180 degrees, and 270 degrees (hereinafter, referred to as “orientation flat angle 4 step method”). The orientation flat angle denotes an angle to the axis perpendicular to the orientation flat of semiconductor substrate (wafer) 101 when viewed from above. By the implantation, source drain extension (hereinafter, abbreviated as “SDE”) regions 107c and 107d are formed on the surface of semiconductor substrate 101.

As shown in FIGS. 42 and 43, by using resist pattern 106 as a mask, boron is implanted into the region of semiconductor substrate 101. At this time, the implantation angle to the axis perpendicular to the surface of semiconductor substrate 101 is 38 degrees, implantation energy is 14 KeV, and a dose is 4×10¹³/cm². Implantation is carried out by the orientation flat angle 4 step method. By the implantation, shallow pocket implantation (hereinafter, abbreviated as “SPI”) regions 109c and 109d are formed on the surface of semiconductor substrate 101.

In resist pattern 106, particularly, in the cases where the orientation flat angle is 90 degrees and 270 degrees, distance L between one side face of gate electrode 105 to the end portion of resist pattern 106 and the film thickness of resist pattern 106 are adjusted so that ions of boron are implanted into the region of semiconductor substrate 101 directly under gate electrode 105. After that, resist pattern 106 is removed.

Subsequently, as shown in FIG. 44, a side wall insulating film 110 is formed on both side faces of gate electrode 105. As shown in FIGS. 45 and 46, a resist pattern 111 is formed on semiconductor substrate 101. By using resist pattern 111 as a mask, arsenic is implanted into the region of semiconductor substrate 101.

At this time, the implantation angle to the axis perpendicular to the surface of semiconductor substrate 101 is 0 degrees, implantation energy is 40 KeV, and a dose is 5×10¹⁵/cm². Implantation is performed by the orientation flat 4 step method. By the implantation, source/drain (hereinafter, described as “S/D”) regions 112c and 112d are formed on the surface of semiconductor substrate 101.

After that, resist pattern 111 is removed, and annealing process and salicide process (which are not shown) are performed, thereby completing a transistor T1.

A second transistor will now be described. First, by processes similar to those of the above-described method, as shown in FIGS. 47 and 48, gate electrode 105 is formed on the surface of semiconductor substrate 101 via gate insulating film 104.

As shown in FIGS. 49 and 50, resist pattern 106 is formed on semiconductor substrate 101. By using resist pattern 106 as a mask, phosphorus is implanted into the region of semiconductor substrate 101. At this time, an implantation angle to the axis perpendicular to the surface of semiconductor substrate 101 is 0 degrees, implantation energy is 50 KeV, and a dose is 1×10¹³/cm².

Implantation is carried out by the orientation flat 4 step method. By the implantation, SDE regions 107g and 107h are formed on the surface of semiconductor substrate 101.

As shown in FIGS. 51 and 52, by using resist pattern 106 as a mask, arsenic is implanted into the region of semiconductor substrate 101.

At this time, the implantation angle to the axis perpendicular to the surface of semiconductor substrate 101 is 45 degrees, implantation energy is 100 KeV, and a dose is 2.8×10¹³/cm². Implantation is carried out by the orientation flat angle 4 step method. By the implantation, lightly doped drain (hereinafter, abbreviated as “LDD”) regions 109g and 109h are formed on the surface of semiconductor substrate 101.

In resist pattern 106, particularly in the cases where the orientation flat angle is 90 degrees and 270 degrees, distance L between one side face of gate electrode 105 to the end portion of resist pattern 106 and the film thickness of resist pattern 106 are adjusted so that ions of arsenic are implanted into the region of semiconductor substrate 101 directly under gate electrode 105. After that, resist pattern 106 is removed.

Subsequently, as shown in FIG. 53, side wall insulating film 110 is formed on both side faces of gate electrode 105. As shown in FIGS. 54 and 55, resist pattern 111 is formed on semiconductor substrate 101. By using resist pattern 111 as a mask, arsenic is implanted into the region of semiconductor substrate 101.

At this time, the implantation angle to the axis perpendicular to the surface of semiconductor substrate 101 is 0 degrees, implantation energy is 40 KeV, and a dose is 5×10¹⁵/cm². Implantation is performed by the orientation flat angle 4 step method. By the implantation, S/D regions 112g and 112h are formed on the surface of semiconductor substrate 101.

After that, resist pattern 111 is removed, and annealing process and salicide process (which are not shown) are performed, thereby completing a transistor T2.

A third transistor will now be described. First, by processes similar to those of the above-described method, as shown in FIGS. 56 and 57, gate electrode 105 is formed on the surface of semiconductor substrate 101 via gate insulating film 104.

As shown in FIGS. 58 and 59, resist pattern 106 is formed on semiconductor substrate 101. By using resist pattern 106 as a mask, arsenic is implanted into the region of semiconductor substrate 101. At this time, an implantation angle to the axis perpendicular to the surface of semiconductor substrate 101 is 0 degrees, implantation energy is 5 KeV, and a dose is 5×10¹⁴/cm².

Implantation is carried out by the orientation flat angle 4 step method. By the implantation, SDE regions 107a and 107b are formed on the surface of semiconductor substrate 101.

As shown in FIGS. 60 and 61, by using resist pattern 106 as a mask, boron is implanted into the region of semiconductor substrate 101.

At this time, the implantation angle to the axis perpendicular to the surface of semiconductor substrate 101 is 38 degrees, implantation energy is 14 KeV, and a dose is 2.4×10¹³/cm². Implantation is carried out in three steps of the orientation flat angles of 0 degrees, 90 degrees, and 180 degrees (hereinafter, referred to as “orientation flat angle 3 step method”). The orientation flat angle denotes an angle to the axis perpendicular to the orientation flat of semiconductor substrate (wafer) 101 when viewed from above. By the implantation, SPI regions 109a and 109b are formed on the surface of semiconductor substrate 101.

In resist pattern 106, particularly in the case where the orientation flat angle is 90 degrees, distance A between one side face of gate electrode 105 to the end portion of resist pattern 106 and the film thickness of resist pattern 106 are adjusted so that ions of boron are implanted into the region of semiconductor substrate 101 directly under gate electrode 105. After that, resist pattern 106 is removed.

Subsequently, as shown in FIG. 62, side wall insulating film 110 is formed on both side faces of gate electrode 105. As shown in FIGS. 63 and 64, resist pattern 111 is formed on semiconductor substrate 101. By using resist pattern 111 as a mask, arsenic is implanted into the region of semiconductor substrate 101.

At this time, the implantation angle to the axis perpendicular to the surface of semiconductor substrate 101 is 0 degrees, implantation energy is 40 KeV, and a dose is 5×10¹⁵/cm². Implantation is performed by the orientation flat angle 4 step method. By the implantation, S/D regions 112a and 112b are formed on the surface of semiconductor substrate 101.

After that, resist pattern 111 is removed, and annealing process and salicide process (which are not shown) are performed, thereby completing a transistor T3.

A fourth transistor will now be described. First, by processes similar to those of the above-described method, as shown in FIGS. 65 and 66, gate electrode 105 is formed on the surface of semiconductor substrate 101 via gate insulating film 104.

As shown in FIGS. 67 and 68, resist pattern 106 is formed on semiconductor substrate 101. By using resist pattern 106 as a mask, phosphorus is implanted into the region of semiconductor substrate 101. At this time, an implantation angle to the axis perpendicular to the surface of the semiconductor substrate 101 is 0 degrees, implantation energy is 20 KeV, and a dose is 1×10¹³/cm².

Implantation is carried out by the orientation flat angle 4 step method. By the implantation, SDE regions 107e and 107f are formed on the surface of semiconductor substrate 101.

As shown in FIGS. 69 and 70, by using resist pattern 106 as a mask, arsenic is implanted into the region of semiconductor substrate 101. At this time, the implantation angle to the axis perpendicular to the surface of semiconductor substrate 101 is 45 degrees, implantation energy is 100 KeV, and a dose is 2.8×10¹³/cm². Implantation is carried out by the orientation flat angle 3 step method. By the implantation, LDD regions 109e and 109f are formed on the surface of semiconductor substrate 101.

In resist pattern 106, particularly in the case where the orientation flat angle is 90 degrees, distance L between one side face of gate electrode 105 to the end portion of resist pattern 106 and the film thickness of resist pattern 106 are adjusted so that ions of arsenic are implanted into the region of semiconductor substrate 101 directly under gate electrode 105. After that, resist pattern 106 is removed.

Subsequently, as shown in FIG. 71, side wall insulating film 110 is formed on both side faces of gate electrode 105. As shown in FIGS. 72 and 73, resist pattern 111 is formed on semiconductor substrate 101. By using resist pattern 111 as a mask, arsenic is implanted into the region of semiconductor substrate 101.

At this time, the implantation angle to semiconductor substrate 101 is 0 degrees, implantation energy is 40 KeV, and a dose is 5×10¹⁵/cm². Implantation is performed by the orientation flat angle 4 step method. By the implantation, S/D regions 112e and 112f are formed on the surface of semiconductor substrate 101.

After that, resist pattern 111 is removed, and annealing process and salicide process (which are not shown) are performed, thereby completing a transistor T4.

A fifth transistor will now be described. First, by processes similar to those of the above-described method, as shown in FIGS. 74 and 75, gate electrode 105 is formed on the surface of semiconductor substrate 101 via gate insulating film 104.

As shown in FIGS. 76 and 77, resist pattern 106 is formed on semiconductor substrate 101. By using resist pattern 106 as a mask, arsenic is implanted into the region of semiconductor substrate 101. At this time, an implantation angle to the axis perpendicular to the surface of semiconductor substrate 101 is 0 degrees, implantation energy is 5 KeV, and a dose is 5×10¹⁴/cm².

Implantation is carried out by the orientation flat angle 4 step method. By the implantation, SDE regions 107i and 107j are formed on the surface of semiconductor substrate 101.

As shown in FIGS. 78 and 79, by using resist pattern 106 as a mask, boron is implanted into the region of semiconductor substrate 101. At this time, the implantation angle to the axis perpendicular to the surface of semiconductor substrate 101 is 38 degrees, implantation energy is 14 KeV, and a dose is 2.4×10¹³/cm². Implantation is carried out in two steps of the orientation flat angles of 0 degrees and 180 degrees. The orientation flat angle denotes an angle to the axis perpendicular to the orientation flat of semiconductor substrate (wafer) 101 when viewed from above. By the implantation, LDD regions 109i and 109j are formed on the surface of semiconductor substrate 101. After that, resist pattern 106 is removed.

Subsequently, as shown in FIG. 80, side wall insulating film 110 is formed on both side faces of gate electrode 105. As shown in FIGS. 81 and 82, resist pattern 111 is formed on semiconductor substrate 101. By using resist pattern 111 as a mask, arsenic is implanted into the region of semiconductor substrate 101.

At this time, the implantation angle to the axis perpendicular to the surface of semiconductor substrate 101 is 0 degrees, implantation energy is 40 KeV, and a dose is 5×10¹⁵/cm². Implantation is performed by the orientation flat angle 4 step method. By the implantation, S/D regions 112i and 112j are formed on the surface of semiconductor substrate 101.

After that, resist pattern 111 is removed, and annealing process and salicide process (which are not shown) are performed, thereby completing a transistor T5.

A sixth transistor will now be described. First, by processes similar to those of the above-described method, as shown in FIGS. 83 and 84, gate electrode 105 is formed on the surface of semiconductor substrate 101 via gate insulating film 104.

As shown in FIGS. 85 and 86, resist pattern 106 is formed on semiconductor substrate 101. By using resist pattern 106 as a mask, phosphorus is implanted into the region of semiconductor substrate 101. At this time, an implantation angle to the axis perpendicular to the surface of semiconductor substrate 101 is 0 degrees, implantation energy is 20 KeV, and a dose is 1×10¹³/cm².

Implantation is carried out by the orientation flat angle 4 step method. By the implantation, SDE regions 107k and 107m are formed on the surface of semiconductor substrate 101.

As shown in FIGS. 87 and 88, by using resist pattern 106 as a mask, arsenic is implanted into the region of semiconductor substrate 101. At this time, the implantation angle to the axis perpendicular to the surface of semiconductor substrate 101 is 45 degrees, implantation energy is 100 KeV, and a dose is 2.3×10¹³/cm². Implantation is carried out by the orientation flat angle 2 step method. By the implantation, LDD regions 109k and 109m are formed on the surface of semiconductor substrate 101. After that, resist pattern 106 is removed.

Subsequently, as shown in FIG. 89, side wall insulating film 110 is formed on both side faces of gate electrode 105. As shown in FIGS. 90 and 91, resist pattern 111 is formed on semiconductor substrate 101. By using resist pattern 111 as a mask, arsenic is implanted into the region of semiconductor substrate 101.

At this time, the implantation angle to the axis perpendicular to the surface of semiconductor substrate 101 is 0 degrees, implantation energy is 40 KeV, and a dose is 5×10¹⁵/cm². Implantation is performed by the orientation flat angle 4 step method. By the implantation, S/D regions 112k and 112m are formed on the surface of semiconductor substrate 101.

After that, resist pattern 111 is removed, and annealing process and salicide process (which are not shown) are performed, thereby completing a transistor T6.

Conventionally, transistors of different kinds are formed as described above.

The conventional method of fabricating a semiconductor device including transistors of different kinds, however, has the following problems.

For example, in the case of forming transistors T1 and T3 on the same semiconductor substrate 101, particularly, the number of steps of orientation flat angles using an angle to the axis perpendicular to the orientation flat of semiconductor substrate (wafer) 101 when viewed from above as a reference in the process of implanting boron to form SPI regions 109c and 109d of transistor T1 and that in the process of implanting boron to form SPI regions 109a and 109b in transistor T3 are different from each other.

That is, the implantation condition at the time of forming SPI regions 109c and 109d of transistor T1 and that at the time of forming SPI regions 109a and 1019b of transistor T3 are different from each other. Consequently, SPI regions 109c and 109d of transistor T1 and SPI regions 109a and 109b of transistor T3 have to be formed in different processes.

Similarly, for example, the implantation condition at the time of forming LDD regions 109g and 109h of transistor T2 and that at the time of forming LDD regions 109e and 109f of transistor T4 are different from each other.

Further, for example, the implantation condition at the time of forming SPI regions 109c and 109d of transistor T1 and that at the time of forming LDD regions 109i and 109j of transistor T5 are different from each other. The implantation condition at the time of forming LDD regions 109g and 109h of transistor T2 and that at the time of forming LDD regions 109k and 109m of transistor T6 are different from each other.

As described above, particularly, the implantation conditions at the time of forming the SPI regions or LDD regions are different from each other. Therefore, in the case of forming transistors T1 to T6 of different kinds on the same semiconductor substrate 101, implantation processes corresponding to the respective kinds of transistors are necessary, and a problem such that the number of processes increases arises.

### SUMMARY OF THE INVENTION

The present invention has been achieved to solve the problem and an object of the present invention is to provide a transistor fabricating method capable of forming transistors of different kinds on a semiconductor substrate without increasing the number of processes.

A method of fabricating a transistor according to the present invention includes the steps of: forming an electrode portion on a main surface of a semiconductor substrate of a first conductive type via an insulating film; and forming a predetermined impurity region in each of a region in the semiconductor substrate positioned on the side of one of side faces of the electrode portion, and a region in the semiconductor substrate positioned on the side of the other side face of the electrode portion. The step of forming the electrode portion includes a step of forming a first electrode portion and a second electrode portion. The step of forming the impurity region includes: a step of forming a resist pattern having a predetermined film thickness including a portion for exposing a first surface of the semiconductor substrate from the one of side faces of the first electrode portion to a position apart from the first electrode portion by a first distance and exposing a second surface of the semiconductor substrate from the other side face of the first electrode portion to a position apart from the first electrode portion by a second distance, and a portion for exposing a third surface of the semiconductor substrate from the one of side faces of the second electrode portion to a position apart from the second electrode portion by a third distance and exposing a fourth surface of the semiconductor substrate from the other side face of the second electrode to a position apart from the second electrode by a fourth distance; and a step of introducing an impurity of a predetermined conductive type by using the resist pattern as a mask. In the step of forming the resist pattern, the predetermined film thickness and at least the first distance are set so as to prevent the impurity of the predetermined conductive type from being obliquely introduced from the one of the side faces into the portion of the region in the semiconductor substrate positioned directly under the first electrode at a predetermined angle with respect to the semiconductor substrate. The predetermined film thickness, the third distance, and the fourth distance are set so that the impurity of the predetermined conductive type is introduced obliquely to the portion of the region in the semiconductor substrate positioned directly under the second electrode from the one of side faces and the other side face at the predetermined angle with respect to the semiconductor substrate.

According to the method of fabricating the transistor, particularly, the predetermined film thickness and at least the first distance are set so as to prevent the impurity of the predetermined conductive type from being obliquely introduced from the one of the side faces into the portion of the region in the semiconductor substrate positioned directly under the first electrode at a predetermined angle with respect to the semiconductor substrate. By the operation, an impurity region which substantially does not include the portion positioned in the region of the semiconductor substrate directly under the first electrode portion is formed at least in the region of the semiconductor substrate positioned on one of side faces of the first electrode portion. Consequently, a transistor including the first electrode portion and the impurity region which is formed in the region of the semiconductor substrate positioned on the side of one of side faces of the first electrode portion and which does not include the portion positioned in the region of the semiconductor substrate directly under the first electrode portion is formed. On the other hand, the predetermined film thickness, the third distance, and the fourth distance are set so that the impurity of the predetermined conductive type is introduced obliquely to the portion of the region in the semiconductor substrate positioned directly under the second electrode from the one of side faces and the other side face at the predetermined angle with respect to semiconductor substrate. By the operation, in each of the region of the semiconductor substrate positioned on the side of one of side faces of the second electrode portion and the region of the semiconductor substrate positioned on the other side face, the impurity region including the portion positioned in the region of the semiconductor substrate directly under the second electrode portion is formed. Consequently, another transistor having the second electrode portion and the impurity region including the portion positioned in the region of the semiconductor substrate directly under the second electrode portion, which is formed in the region of the semiconductor substrate positioned on each of the side faces of the second electrode is formed. In the another transistor, the impurity regions each including the portion positioned in the region of the semiconductor substrate directly under the second electrode portion are formed symmetric with respect to the second electrode portion. In such a manner, one transistor and another transistor having different shapes of the impurity regions can be formed on the same semiconductor substrate without adding a process.

In the step of forming the resist pattern, preferably, the predetermined film thickness and the second distance are set so that the impurity of the predetermined conductive type is introduced obliquely into the portion of the region in the semiconductor substrate positioned directly under the first electrode portion from the other side face at the predetermined angle with respect to the semiconductor substrate.

By the operation, in the region of the semiconductor substrate positioned on the side of the other side face of the first electrode portion in the one transistor, the impurity region including the portion positioned in the region of the semiconductor substrate directly under the first electrode portion is formed. As a result, in the one transistor, the impurity region including the portion positioned in the region of the semiconductor substrate directly under the first electrode portion and the impurity region which does not include such a portion are formed, and the impurity regions are formed not symmetric with respect to the first electrode portion.

Alternately, in the step of forming a resist pattern, preferably, the predetermined film thickness and the second distance are set so as to prevent the impurity of the predetermined conduction time from obliquely introduced into the portion of the region in the semiconductor substrate positioned directly under the first electrode portion from the other side face at a predetermined angle with respect to the semiconductor substrate.

By the operation, in the region of the semiconductor substrate positioned on the side of the other side face of the first electrode portion in one transistor, the impurity region which does not include the portion positioned in the region of the semiconductor substrate directly under the first electrode portion is formed. As a result, in the one transistor, the impurity regions which do not include the portion positioned in the region of the semiconductor substrate directly under the first electrode portion are formed symmetric with respect to the first electrode portion.

More specifically, preferably, the step of forming the impurity region includes a step of forming a first impurity region of a second conductive type in the first surface, forming a second impurity region of the second conductive type in the second surface, forming a third impurity region of the second conductive type in the third surface, and forming a fourth impurity region of the second conductive type in the fourth surface by introducing an impurity of the second conductive type as the impurity of the predetermined conductive type substantially perpendicular with respect to the semiconductor substrate.

By the process, the first and second impurity regions in the one transistor become what is called SDE regions, and the third and fourth regions in another transistor become what is called SDE regions.

Further, it is preferable that the step of forming the impurity region includes a step of forming a fifth impurity region of the first conductive type on the first surface, forming a sixth impurity region of the first conductive type on the second surface, forming a seventh impurity region of the first conductive type on the third surface, and forming an eighth impurity region of the first conductive type on the fourth surface by introducing an impurity of the first conductive type as the impurity of the predetermined conductive type at the predetermined angle with respect to the semiconductor substrate.

By the process, at least the fifth impurity region in one transistor becomes what is called an SPI region which does not include the portion positioned in the region of the semiconductor substrate directly under the first electrode portion. The seventh and eighth impurity regions in another transistor become what is called SPI regions including the portion positioned in the region of the semiconductor substrate directly under the second electrode portion.

Alternately, it is preferable that the step of forming the impurity region includes a step of forming a fifth impurity region of the second conductive type on the first surface, forming a sixth impurity region of the second conductive type on the second surface, forming a seventh impurity region of the second conductive type on the third surface, and forming an eighth impurity region of the second conductive type on the fourth surface by introducing an impurity of the second conductive type as the impurity of the predetermined conductive type at the predetermined angle with respect to the semiconductor substrate.

By the process, at least the fifth impurity region in one transistor becomes what is called an LDD region which does not include the portion positioned in the region of the semiconductor substrate directly under the first electrode portion. The seventh and eighth impurity regions in another transistor become what is called LDD regions including the portion positioned in the region of the semiconductor substrate directly under the second electrode portion.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a sectional view taken along line I-I of FIG. 2, showing a process of a method of fabricating a semiconductor device according to a first embodiment of the present invention;

FIG. 2 is a plan view of the process shown in FIG. 1 in the first embodiment;

FIG. 3 is a sectional view taken along line III-III in FIG. 4, showing a process performed after the process illustrated in FIG. 1 in the first embodiment;

FIG. 4 is a plan view of the process shown in FIG. 3 in the first embodiment;

FIG. 5 is a sectional view taken along line V-V of FIG. 6, showing a process performed after the process illustrated in FIG. 3 in the first embodiment;

FIG. 6 is a plan view of the process shown in FIG. 5 in the first embodiment;

FIG. 7 is a sectional view showing a process performed after the process illustrated in FIG. 5 in the first embodiment;

FIG. 8 is a sectional view taken along line VIII-VIII in FIG. 9, showing a process performed after the process illustrated in FIG. 7 in the first embodiment;

FIG. 9 is a plan view showing the process illustrated in FIG. 8 in the first embodiment;

FIG. 10 is a perspective view showing an orientation flat angle and an implantation angle in the first embodiment;

FIG. 11 is a sectional view taken along line XI-XI in FIG. 12, showing a process of a method of fabricating a semiconductor device according to a second embodiment of the present invention;

FIG. 12 is a plan view of the process shown in FIG. 11 in the second embodiment;

FIG. 13 is a sectional view taken along line XIII-XIII in FIG. 14, showing a process performed after the process illustrated in FIG. 11 in the second embodiment;

FIG. 14 is a plan view of the process shown in FIG. 13 in the second embodiment;

FIG. 15 is a sectional view taken along line XV-XV in FIG. 16, showing a process performed after the process illustrated in FIG. 13 in the second embodiment;

FIG. 16 is a plan view of the process shown in FIG. 15 in the second embodiment;

FIG. 17 is a sectional view showing a process performed after the process illustrated in FIG. 15 in the second embodiment;

FIG. 18 is a sectional view taken along line XVIII-XVIII in FIG. 19, showing a process performed after the process illustrated in FIG. 17 in the second embodiment;

FIG. 19 is a plan view showing the process illustrated in FIG. 18 in the second embodiment;

FIG. 20 is a sectional view taken along line XX-XX in FIG. 21, showing a method of fabricating a semiconductor device according to a third embodiment of the present invention;

FIG. 21 is a plan view of the process shown in FIG. 20 in the third embodiment;

FIG. 22 is a sectional view taken along line XXII-XXII in FIG. 23, showing a process performed after the process illustrated in FIG. 20 in the third embodiment;

FIG. 23 is a plan view of the process shown in FIG. 22 in the third embodiment;

FIG. 24 is a sectional view taken along line XXIV-XXIV in FIG. 25, showing a process performed after the process illustrated in FIG. 22 in the third embodiment;

FIG. 25 is a plan view of the process shown in FIG. 24 in the third embodiment;

FIG. 26 is a sectional view showing a process performed after the process of FIG. 24 in the third embodiment;

FIG. 27 is a sectional view taken along line XXVII-XXVII in FIG. 28, showing a process performed after the process illustrated in FIG. 26 in the third embodiment;

FIG. 28 is a plan view showing the process illustrated in FIG. 27 in the third embodiment;

FIG. 29 is a sectional view taken along line XXIX-XXIX in FIG. 30, showing a process of a method of fabricating a semiconductor device according to a fourth embodiment of the present invention;

FIG. 30 is a plan view of the process shown in FIG. 29 in the fourth embodiment;

FIG. 31 is a sectional view taken along line XXXI-XXXI in FIG. 32, showing a process performed after the process illustrated in FIG. 29 in the fourth embodiment;

FIG. 32 is a plan view of the process shown in FIG. 31 in the fourth embodiment;

FIG. 33 is a sectional view taken along line XXXIII-XXXIII in FIG. 34, showing a process performed after the process illustrated in FIG. 31 in the fourth embodiment;

FIG. 34 is a plan view of the process shown in FIG. 33 in the fourth embodiment;

FIG. 35 is a sectional view showing a process performed after the process illustrated in FIG. 33 in the fourth embodiment;

FIG. 36 is a sectional view taken along line XXXVI-XXXVI in FIG. 37, showing a process performed after the process illustrated in FIG. 35 in the fourth embodiment;

FIG. 37 is a plan view showing the process illustrated in FIG. 36 in the fourth embodiment;

FIG. 38 is a sectional view taken along line XXXVIII-XXXVIII in FIG. 39, showing a process in a method of fabricating a semiconductor device in a first conventional technique;

FIG. 39 is a plan view of the process illustrated in FIG. 38;

FIG. 40 is a sectional view taken along line XL-XL in FIG. 41, showing a process performed after the process illustrated in FIG. 38;

FIG. 41 is a plan view of the process shown in FIG. 40;

FIG. 42 is a sectional view taken along line XLII-XLII in FIG. 43, showing a process performed after the process illustrated in FIG. 40;

FIG. 43 is a plan view of the process shown in FIG. 42;

FIG. 44 is a sectional view showing a process performed after the process illustrated in FIG. 42;

FIG. 45 is a sectional view taken along line XLV-XLV in FIG. 46, showing a process performed after the process illustrated in FIG. 44;

FIG. 46 is a plan view of the process shown in FIG. 45;

FIG. 47 is a sectional view taken along line XLVII-XLVII in FIG. 48, showing a process in a method of fabricating a semiconductor device in a second conventional technique;

FIG. 48 is a plan view of the process illustrated in FIG. 47;

FIG. 49 is a sectional view taken along line XLIX-XLIX in FIG. 50, showing a process performed after the process illustrated in FIG. 47;

FIG. 50 is a plan view of the process shown in FIG. 49;

FIG. 51 is a sectional view taken along line LI-LI in FIG. 52, showing a process performed after the process illustrated in FIG. 49;

FIG. 52 is a plan view of the process shown in FIG. 51;

FIG. 53 is a sectional view showing a process performed after the process illustrated in FIG. 51;

FIG. 54 is a sectional view taken along line LIV-LIV in FIG. 55, showing a process performed after the process illustrated in FIG. 53;

FIG. 55 is a plan view of the process shown in FIG. 54;

FIG. 56 is a sectional view taken along line LVI-LVI in FIG. 57, showing a process in a method of fabricating a semiconductor device in a third conventional technique;

FIG. 57 is a plan view of the process illustrated in FIG. 56;

FIG. 58 is a sectional view taken along line LVIII-LVIII in FIG. 59, showing a process performed after the process illustrated in FIG. 56;

FIG. 59 is a plan view of the process shown in FIG. 58;

FIG. 60 is a sectional view taken along line LX-LX in FIG. 61, showing a process performed after the process illustrated in FIG. 58;

FIG. 61 is a plan view of the process shown in FIG. 60;

FIG. 62 is a sectional view showing a process performed after the process illustrated in FIG. 60;

FIG. 63 is a sectional view taken along line LXIII-LXIII in FIG. 64, showing a process performed after the process illustrated in FIG. 62;

FIG. 64 is a plan view of the process shown in FIG. 63;

FIG. 65 is a sectional view taken along line LXV-LXV in FIG. 66, showing a process in a method of fabricating a semiconductor device in a fourth conventional technique;

FIG. 66 is a plan view of the process illustrated in FIG. 65;

FIG. 67 is a sectional view taken along line LXVII-LXVII in FIG. 68, showing a process performed after the process illustrated in FIG. 65;

FIG. 68 is a plan view of the process shown in FIG. 67;

FIG. 69 is a sectional view taken along line LXIX-LXIX in FIG. 70, showing a process performed after the process illustrated in FIG. 67;

FIG. 70 is a plan view of the process shown in FIG. 69;

FIG. 71 is a sectional view showing a process performed after the process illustrated in FIG. 69;

FIG. 72 is a sectional view taken along line LXXII-LXXII in FIG. 73, showing a process performed after the process illustrated in FIG. 71;

FIG. 73 is a plan view of the process shown in FIG. 72;

FIG. 74 is a sectional view taken along line LXXIV-LXXIV in FIG. 75, showing a process in a method of fabricating a semiconductor device in a fifth conventional technique;

FIG. 75 is a plan view of the process illustrated in FIG. 74;

FIG. 76 is a sectional view taken along line LXXVI-LXXVI in FIG. 77, showing a process performed after the process illustrated in FIG. 74;

FIG. 77 is a plan view of the process shown in FIG. 76;

FIG. 78 is a sectional view taken along line LXXVIII-LXXVIII in FIG. 79, showing a process performed after the process illustrated in FIG. 76;

FIG. 79 is a plan view of the process shown in FIG. 78;

FIG. 80 is a sectional view showing a process performed after the process illustrated in FIG. 78;

FIG. 81 is a sectional view taken along line LXXXI-LXXXI in FIG. 82, showing a process performed after the process illustrated in FIG. 80;

FIG. 82 is a plan view of the process shown in FIG. 81;

FIG. 83 is a sectional view taken along line LXXXIII-LXXXIII in FIG. 84, showing a process in a method of fabricating a semiconductor device in a sixth conventional technique;

FIG. 84 is a plan view of the process illustrated in FIG. 83;

FIG. 85 is a sectional view taken along line LXXXV-LXXXV in FIG. 86, showing a process performed after the process illustrated in FIG. 83;

FIG. 86 is a plan view of the process shown in FIG. 85;

FIG. 87 is a sectional view taken along line LXXXVII-LXXXVII in FIG. 88, showing a process performed after the process illustrated in FIG. 85;

FIG. 88 is a plan view of the process shown in FIG. 87;

FIG. 89 is a sectional view showing a process performed after the process illustrated in FIG. 87;

FIG. 90 is a sectional view taken along line XC-XC in FIG. 91, showing a process performed after the process illustrated in FIG. 89; and

FIG. 91 is a plan view of the process shown in FIG. 90.

### DESCRIPTION OF THE PREFERRED EMBODIMENTS

First Embodiment

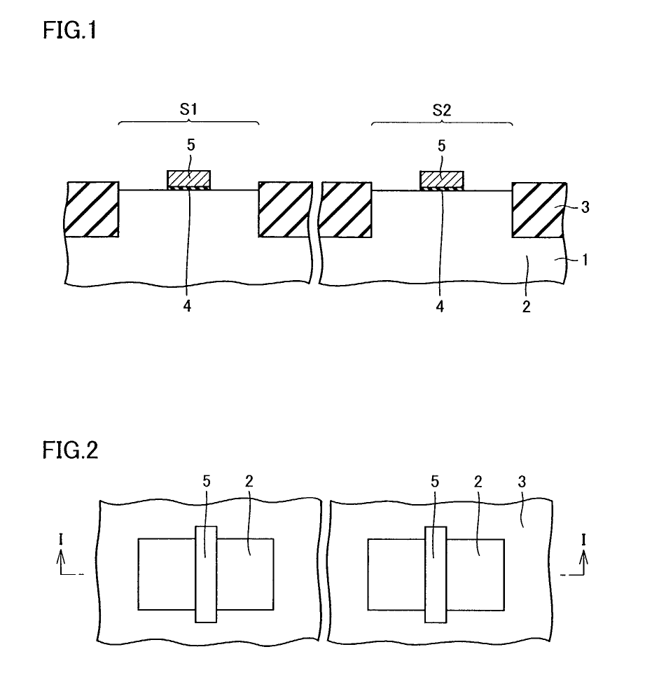

A method of fabricating a semiconductor device according to a first embodiment of the present invention will be described. As shown in FIGS. 1 and 2, a trench isolation oxide film 3 for providing element formation regions S1 and S2 is formed in the main surface of a semiconductor substrate 1. In element formation region S1 and S2, for example, by implanting p-type impurity ions, p-type wells 2 are formed. A gate electrode 5 is formed on the surface of each of element formation regions S1 and S2 in semiconductor substrate 1 via a gate insulating film 4.

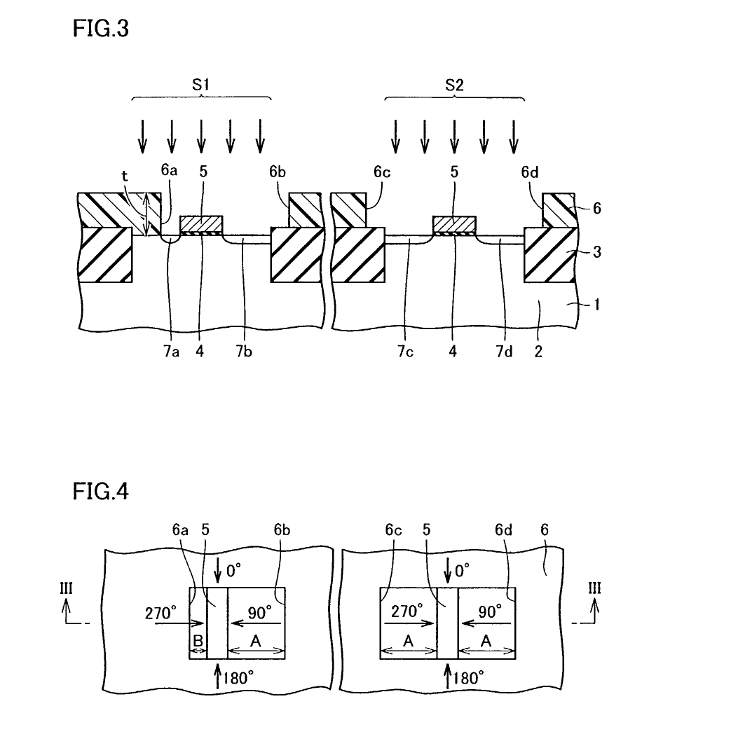

As shown in FIGS. 3 and 4, a predetermined resist pattern 6 is formed on semiconductor substrate 1. By using resist pattern 6 as a mask, arsenic is implanted into the region of semiconductor substrate 1. At this time, an implantation angle to the axis perpendicular to the surface of semiconductor substrate 1 is 0 degrees, implantation energy is 5 KeV, and a dose is 5×10¹⁴/cm².

Implantation is carried out in four steps of orientation flat angles of 0 degrees, 90 degrees, 180 degrees, and 270 degrees (orientation flat angle 4 step method). The orientation flat angle denotes an angle to the axis perpendicular to the orientation flat of semiconductor substrate (wafer) 101 when viewed from above. By the implantation, SDE regions 7a and 7b are formed on the surface of element formation region S1 in semiconductor substrate 1, and SDE regions 7c and 7d are formed on the surface of element formation region S2.

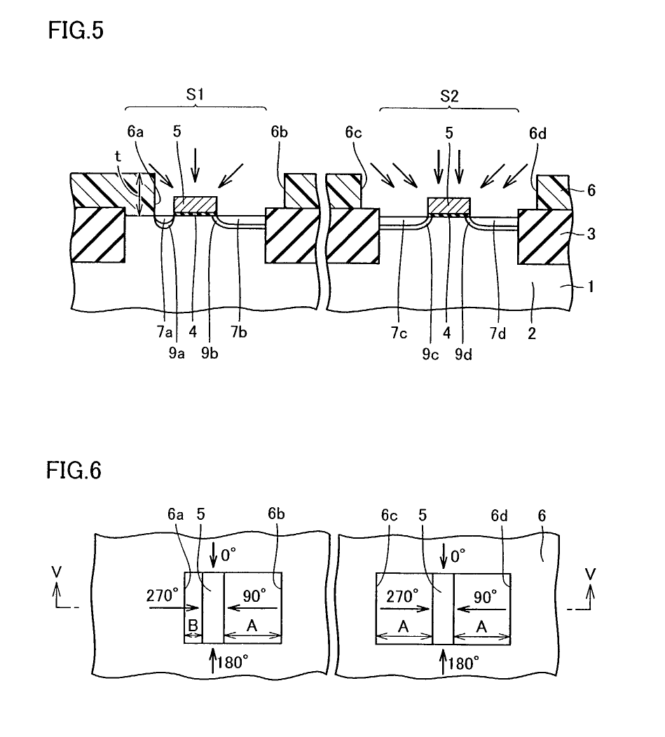

As shown in FIGS. 5 and 6, by using resist pattern 6 formed on semiconductor substrate 1 as a mask, boron is implanted into the region of semiconductor substrate 1. At this time, the implantation angle to the axis perpendicular to the surface of semiconductor substrate 1 is 38 degrees, implantation energy is 14 KeV, and a dose is 4×10¹³/cm². Implantation is carried out by the orientation flat angle 4 step method.

By the implantation, SPI regions 9a and 9b are formed on the surface of element formation region S1 in semiconductor substrate 1, and SPI regions 9c and 9d are formed on the surface of element formation region S2.

As shown in FIG. 6, in resist pattern 6 for element formation region S1, particularly, when the orientation flat angle is 270 degrees, distance B between one side face of gate electrode 5 to an end portion of resist pattern 6 and the film thickness “t” of resist pattern 6 are adjusted so that ions of boron are not implanted into the region of semiconductor substrate 1 directly under gate electrode 5.

Further, when the orientation flat angle is 90 degrees, distance A between the other side face of gate electrode 5 to an end portion of resist pattern 6 and the film thickness “t” of resist pattern 6 are adjusted so that ions of boron are implanted into the region of semiconductor substrate 1 directly under gate electrode 1.

On the other hand, in resist pattern 6 for element formation region S2, particularly in the cases where the orientation flat angle is 90 degrees and 270 degrees, distance A between one side face of gate electrode 5 to an end portion of resist pattern 6 and the film thickness “t” of resist pattern 6 are adjusted so that ions of boron are implanted into the region of semiconductor substrate 1 directly under gate electrode 5. After implantation of boron ions, resist pattern 6 is removed.

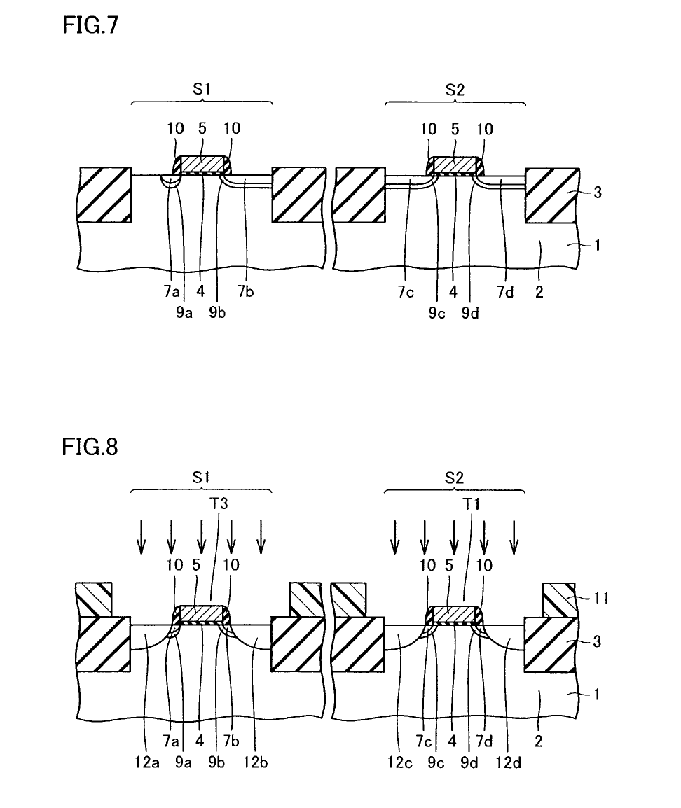

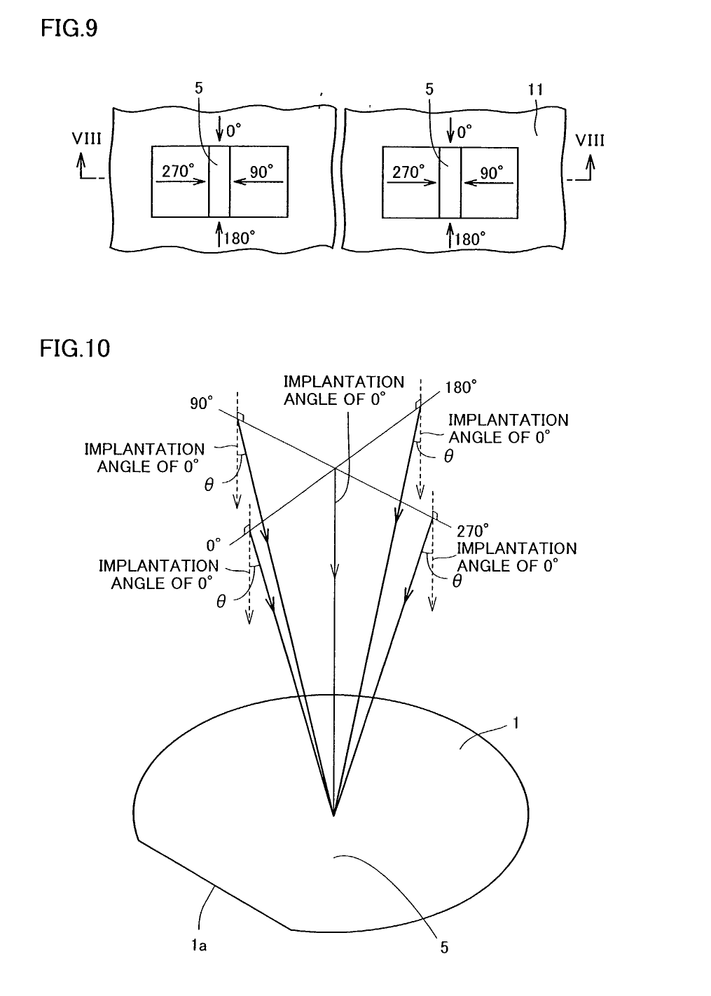

Subsequently, for example, a silicon oxide film (not shown) is formed on semiconductor substrate 1 so as to cover gate electrode 5. By performing anisotropic etching on the silicon oxide film, as shown in FIG. 7, a side wall insulating film 10 is formed on both side faces of gate electrode 5. As shown in FIGS. 8 and 9, a resist pattern 11 is formed on semiconductor substrate 1.

By using resist pattern 11 as a mask, arsenic is implanted into the region of semiconductor substrate 1. At this time, the implantation angle to semiconductor substrate 1 is 0 degrees, implantation energy is 40 KeV, and a dose is 5×10¹⁵/cm². Implantation is performed by the orientation flat angle 4 step method. By the implantation, S/D regions 12a and 12b are formed on the surface of element formation region S1 in semiconductor substrate 1, and S/D regions 12c and 12d are formed on the surface of element formation region S2.

After that, resist pattern 11 is removed, and annealing process and salicide process (which are not shown) are performed, thereby completing a transistor T3 in element formation region S1 and completing a transistor T1 in element formation region S2.

In the method of fabricating the semiconductor device, particularly, in resist pattern 6 used for forming the SPI regions shown in FIGS. 5 and 6, distances A and B and film thickness “t” are adjusted so that boron ions obliquely implanted into element formation region S1 at a predetermined implantation angle from the side of one side face of gate electrode 5 are not implanted into the region of semiconductor substrate 1 positioned directly under gate electrode 5 and, for the other portion, boron ions are implanted into the region in semiconductor substrate 1 positioned directly under gate electrode 5.

As compared with the conventional semiconductor device fabricating method, transistors T1 and T3 of different kinds can be simultaneously formed without adding a new process.

In transistor T1, by using SPI regions 9c and 9d including a portion formed in the region of semiconductor substrate 1 directly under gate electrode 5 as a drain and a source, widening of a depletion layer is suppressed.

In transistor T3, by using, as a drain, SPI region 9b including a portion formed in the region of semiconductor substrate 1 directly under gate electrode 5, widening of the depletion layer is suppressed. By using, as a source, SPI region 9a which does not include the portion formed in the region of semiconductor substrate 1 directly under gate electrode 5, deterioration in mobility can be suppressed.

Second Embodiment

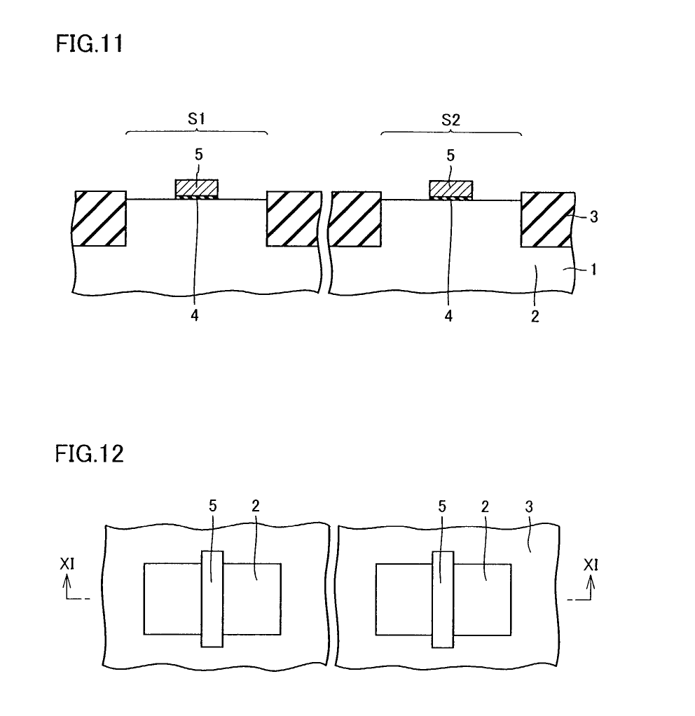

A method of fabricating a semiconductor device according to a second embodiment of the present invention will be described. By performing processes similar to the above-described processes, as shown in FIGS. 11 and 12, gate electrode 5 is formed on the surface of each of element formation regions S1 and S2 via gate insulating film 4.

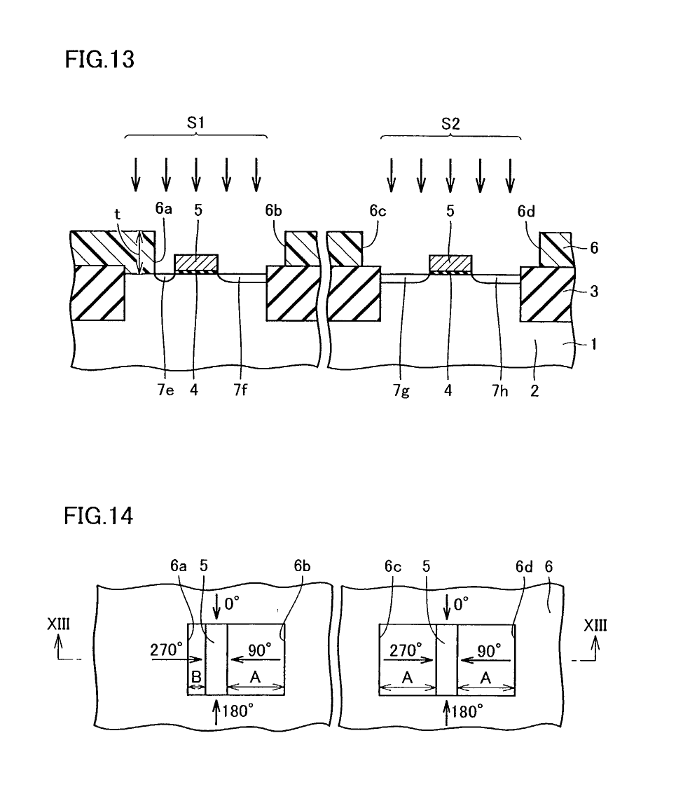

As shown in FIGS. 13 and 14, predetermined resist pattern 6 is formed on semiconductor substrate 1. By using resist pattern 6 as a mask, arsenic is implanted into the region of semiconductor substrate 1. At this time, an implantation angle to the axis perpendicular to the surface of semiconductor substrate 1 is 0 degrees, implantation energy is 20 KeV, and a dose is 1×10¹³/cm². Implantation is carried out by the orientation flat angle 4 step method.

By the implantation, SDE regions, 7e and 7f are formed on the surface of element formation region S1 in semiconductor substrate 1, and SDE regions 7g and 7h are formed on the surface of element formation region S2.

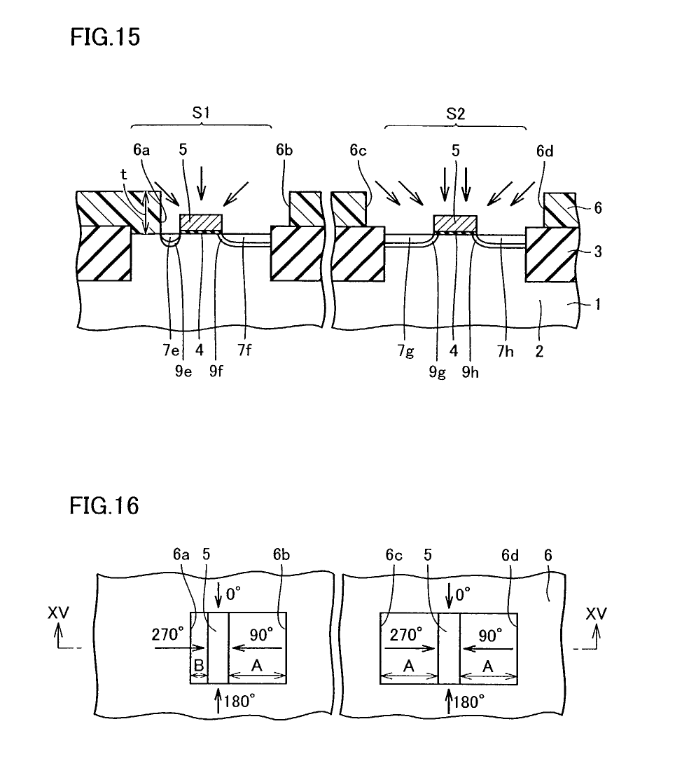

As shown in FIGS. 15 and 16, by using resist pattern 6 formed on semiconductor substrate 1 as a mask, arsenic is implanted into the region of semiconductor substrate 1. At this time, the implantation angle to semiconductor substrate 1 is 45 degrees, implantation energy is 100 KeV, and a dose is 2.8×10¹³/cm². Implantation is carried out by the orientation flat angle 4 step method.

By the implantation, LDD regions 9e and 9f are formed on the surface of element formation region S1 in semiconductor substrate 1, and LDD regions 9g and 9h are formed on the surface of element formation region S2.

As shown in FIG. 16, in resist pattern 6, particularly, when the orientation flat angle is 270 degrees for element formation region S1, distance B between one side face of gate electrode 5 to an end portion of resist pattern 6 and the film thickness “t” of resist pattern 6 are adjusted so that ions of arsenic are not implanted into the region of semiconductor substrate 1 directly under gate electrode 5.

Further, when the orientation flat angle is 90 degrees, distance A between the other side face of gate electrode 5 to an end portion of resist pattern 6 and the film thickness “t” of resist pattern 6 are adjusted so that ions of arsenic are implanted into the region of semiconductor substrate 1 directly under. gate electrode 1.

On the other hand, in resist pattern 6 for element formation region S2, particularly, when the orientation flat angle is 90 degrees and 270 degrees, distance A between one side face of gate electrode 5 to the end portion of resist pattern 6 and the film thickness “t” of resist pattern 6 are adjusted so that ions of arsenic are implanted into the region of semiconductor substrate 1 directly under gate electrode 5. After implantation of arsenic ions, resist pattern 6 is removed.

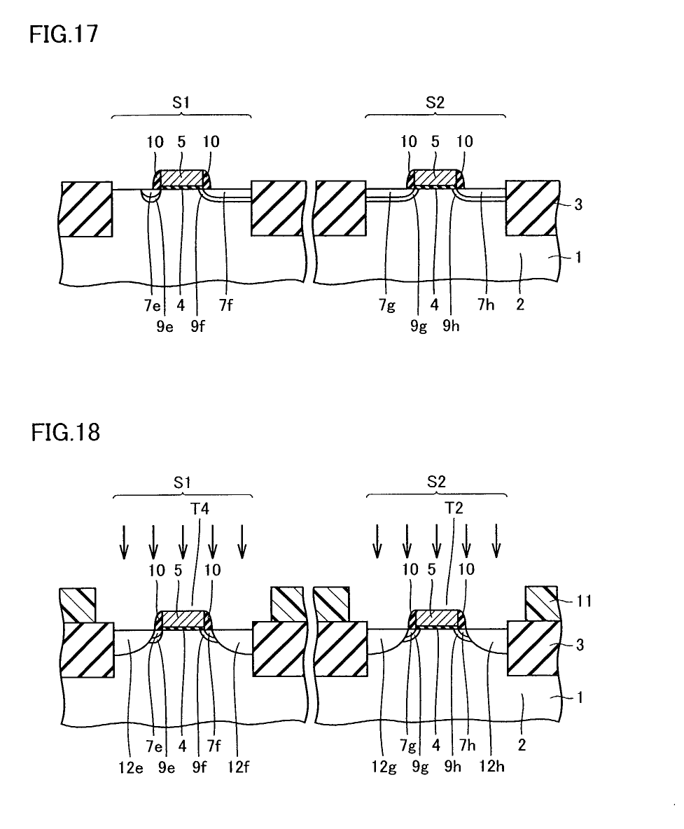

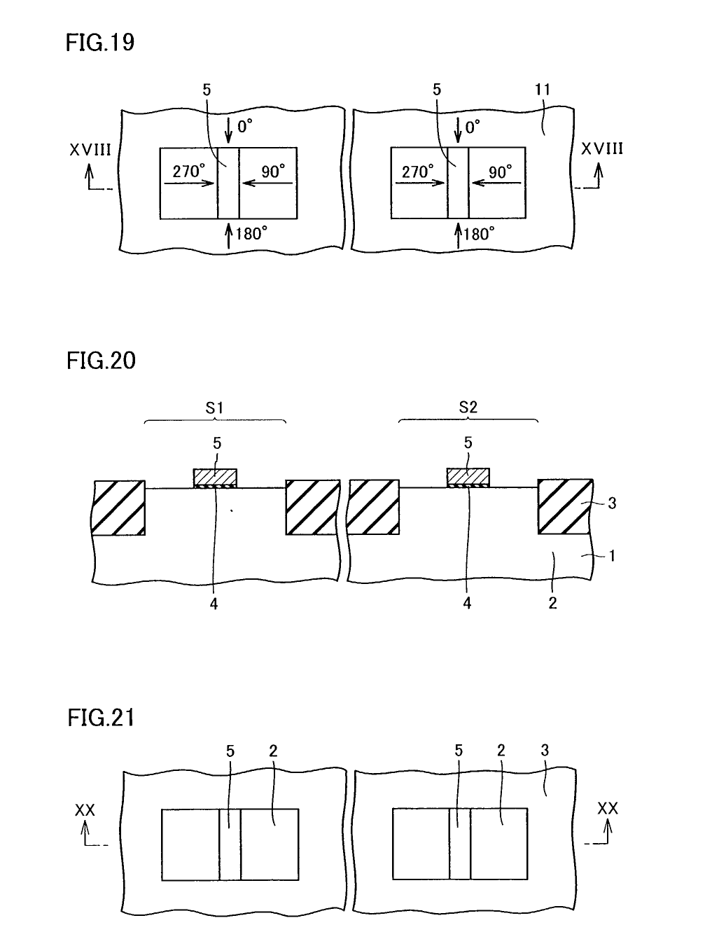

Subsequently, by performing processes similar to the above-described processes, as shown in FIG. 17, side wall insulating film 10 is formed on both side faces of gate electrode 5. After that, as shown in FIGS. 18 and 19, resist pattern 11 is formed on semiconductor substrate 1.

By using resist pattern 11 as a mask, arsenic is implanted into the region of semiconductor substrate 1. At this time, the implantation angle to the axis perpendicular to the surface of semiconductor substrate 1 is 0 degrees, implantation energy is 40 KeV, and a dose is 5×10¹⁵/cm². Implantation is performed by the orientation flat angle 4 step method. By the implantation, SID regions 12e and 12f are formed on the surface of element formation region S1 in semiconductor substrate 1, and S/D regions 12g and 12f are formed on the surface of element formation region S2.

After that, resist pattern 11 is removed, and annealing process and salicide process (which are not shown) are performed, thereby completing a transistor T4 in element formation region S1 and completing a transistor T2 in element formation region S2.

In the method of fabricating the semiconductor device, particularly, in resist pattern 6 used for forming LDD regions shown in FIGS. 15 and 16, distances A and B and film thickness “t” are adjusted so that boron ions obliquely implanted into element formation region S1 at a predetermined implantation angle from the side of one side face of gate electrode 5 are not implanted into the region of semiconductor substrate 1 directly under gate electrode 5 and, for the other portion, boron ions are implanted into the region in semiconductor substrate 1 directly under gate electrode 5.

As compared with the conventional semiconductor device fabricating method, transistors T2 and T4 of different kinds can be simultaneously formed without adding a new process.

In transistor T2, by using LDD regions 9g and 9h including a portion formed in the region of semiconductor substrate 1 directly under gate electrode 5 as a drain and a source, the driving capability of the transistor is improved.

In transistor T4, by using, as a drain, LDD region 9f including the portion formed in the region of semiconductor substrate 1 directly under gate electrode 5, resistance to hot carrier caused by increase in electric field is improved. By using, as a source, LDD region 9e which does not include the portion formed in the region of semiconductor substrate 1 directly under gate electrode 5, parasitic resistance is reduced and the driving capability is improved.

Third Embodiment

A method of fabricating a semiconductor device according to a third embodiment of the present invention will be described. By performing processes similar to the above-described processes, as shown in FIGS. 20 and 21, gate electrode 5 is formed on the surface of each of element formation regions S1 and S2 via gate insulating film 4.

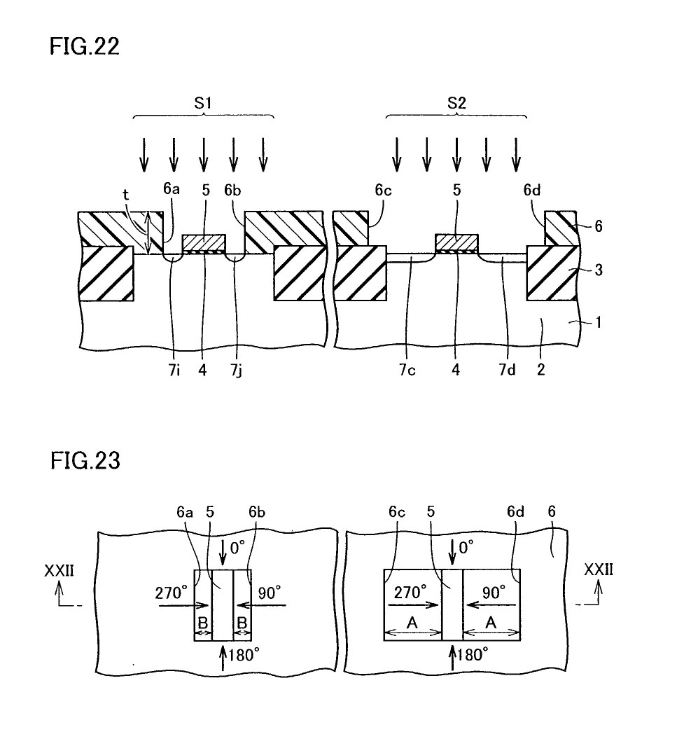

As shown in FIGS. 22 and 23, predetermined resist pattern 6 is formed on semiconductor substrate 1. By using resist pattern 6 as a mask, arsenic is implanted into the region of semiconductor substrate 1. At this time, an implantation angle to the axis perpendicular to the surface of semiconductor substrate 1 is 0 degrees, implantation energy is 5 KeV, and a dose is 1×10¹⁴/cm². Implantation is carried out by the orientation flat angle 4 step method.

By the implantation, SDE regions 7i and 7j are formed on the surface of element formation region S1 in semiconductor substrate 1, and SDE regions 7c and 7d are formed on the surface of element formation region S2.

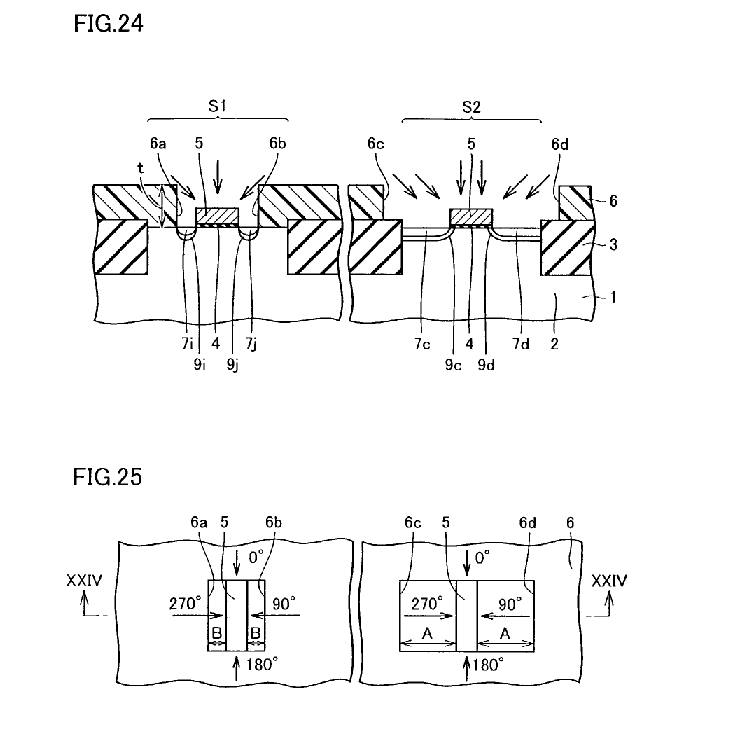

As shown in FIGS. 24 and 25, by using resist pattern 6 formed on semiconductor substrate 1 as a mask, boron is implanted into the region of semiconductor substrate 1. At this time, the implantation angle to the axis perpendicular to the surface of semiconductor substrate 1 is 38 degrees, implantation energy is 14 KeV, and a dose is 2.4×10¹³/cm². Implantation is carried out by the orientation flat angle 4 step method.

By the implantation, SPI regions 9i and 9j are formed on the surface of element formation region S1 in semiconductor substrate 1, and SPI regions 9c and 9d are formed on the surface of element formation region S2.

As shown in FIG. 25, in resist pattern 6, particularly, in the cases where the orientation flat angle is 90 degrees and 270 degrees for element formation region S1, distances B each between one side face of gate electrode 5 to an end portion of resist pattern 6 and the film thickness “t” of resist pattern 6 are adjusted so that ions of boron are not implanted into the region of semiconductor substrate 1 directly under gate electrode 5.

Further, in resist pattern 6 for element formation region S2, particularly in the cases of the orientation flat angle is 90 degrees and 270 degrees, distances A each between one side face of gate electrode 5 to an end portion of resist pattern 6 and the film thickness “t” of resist pattern 6 are adjusted so that ions of boron are implanted into the region of semiconductor substrate 1 directly under gate electrode 5. After implantation of boron ions, resist pattern 6 is removed.

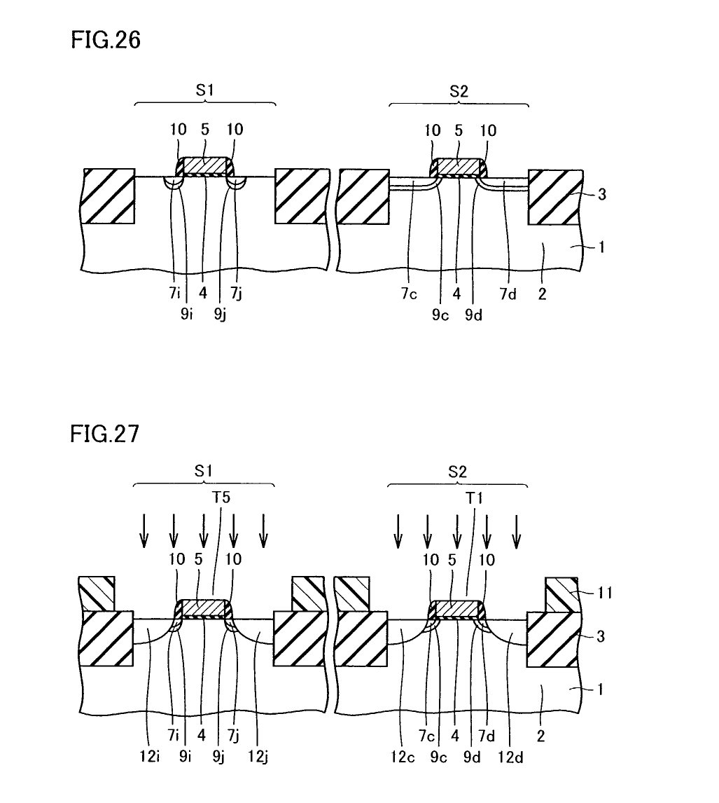

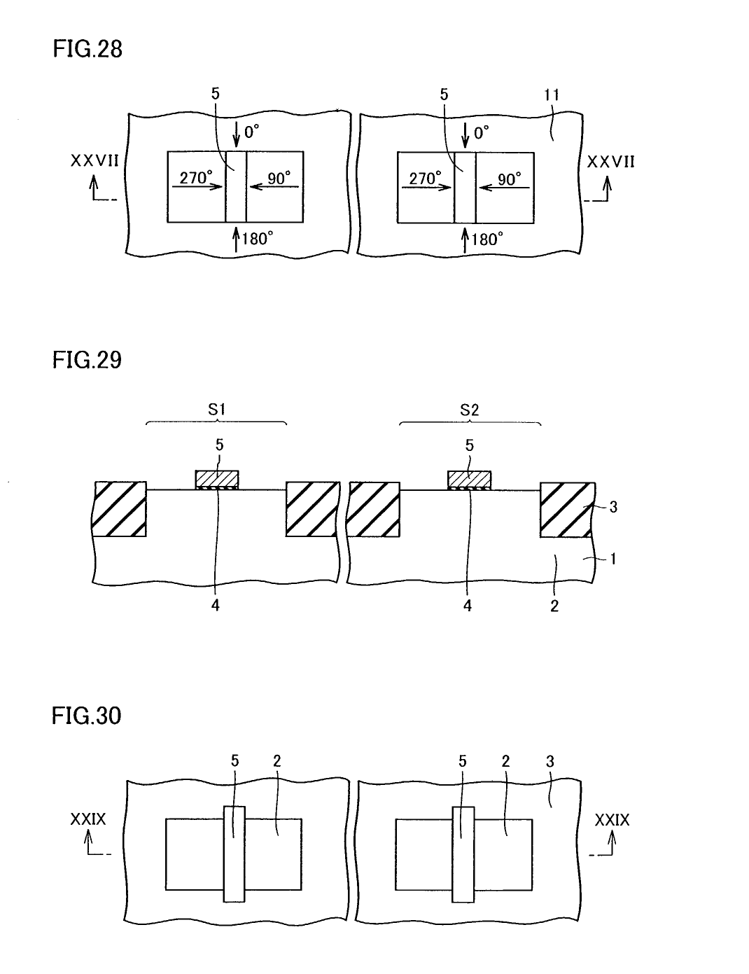

Subsequently, by performing processes similar to the above-described processes, as shown in FIG. 26, side wall insulating film 10 is formed on both side faces of gate electrode 5. As shown in FIGS. 27 and 28, resist pattern 11 is formed on semiconductor substrate 1.

By using resist pattern 11 as a mask, arsenic is implanted into the region of semiconductor substrate 1. At this time, the implantation angle to the axis perpendicular to the surface of semiconductor substrate 1 is 0 degrees, implantation energy is 40 KeV, and a dose is 5×10¹⁵/cm². Implantation is performed by the orientation flat 4 step method. By the implantation, S/D regions 12i and 12j are formed on the surface of element formation region S1 in semiconductor substrate 1, and S/D regions 12c and 12d are formed on the surface of element formation region S2.

After that, resist pattern 11 is removed, and annealing process and salicide process (which are not shown) are performed, thereby completing a transistor T5 in element formation region S1 and completing a transistor T1 in element formation region S2.

In the method of fabricating the semiconductor device, particularly, in resist pattern 6 used for forming SPI regions shown in FIGS. 24 and 25, distances A and B and film thickness “t” are adjusted so that boron ions obliquely implanted into element formation region S1 at a predetermined implantation angle from the side of each of side faces of gate electrode 5 are not implanted into the region of semiconductor substrate 1 positioned directly under gate electrode 5 and, for the other portion, boron ions are implanted into the region in semiconductor substrate 1 positioned directly under gate electrode 5.

As compared with the conventional semiconductor device fabricating method, transistors T1 and T5 of different kinds can be simultaneously formed without adding a new process.

Particularly, in transistor T5, by using, as a drain and a source, SPI regions 9i and 9j which do not include the portion formed in the region of semiconductor substrate 1 positioned directly under gate electrode 5, widening of a depletion layer is not suppressed as much as in the case of transistor T3, so that the driving capability of the transistor is improved.

Fourth Embodiment

A method of fabricating a semiconductor device according to a fourth embodiment of the present invention will be described. By performing processes similar to the above-described processes, as shown in FIGS. 29 and 30, gate electrode 5 is formed on the surface of each of element formation regions S1 and S2 via gate insulating film 4.

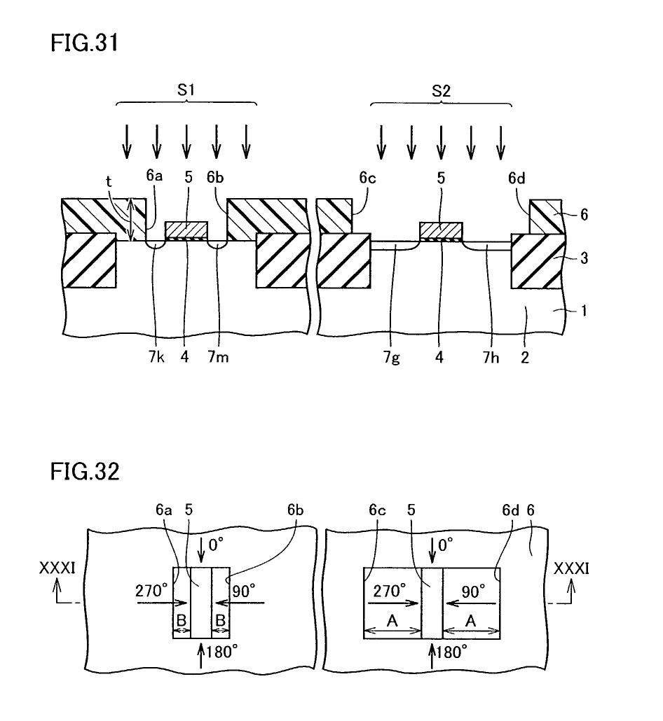

As shown in FIGS. 31 and 32, predetermined resist pattern 6 is formed on semiconductor substrate 1. By using resist pattern 6 as a mask, phosphorus is implanted into the region of semiconductor substrate 1. At this time, an implantation angle to semiconductor substrate 1 is 0 degrees, implantation energy is 20 KeV, and a dose is 1×10¹³/cm². Implantation is carried out by the orientation flat angle 4 step method.

By the implantation, SDE regions 7k and 7m are formed on the surface of element formation region S1 in semiconductor substrate 1, and SDE regions 7g and 7h are formed on the surface of element formation region S2.

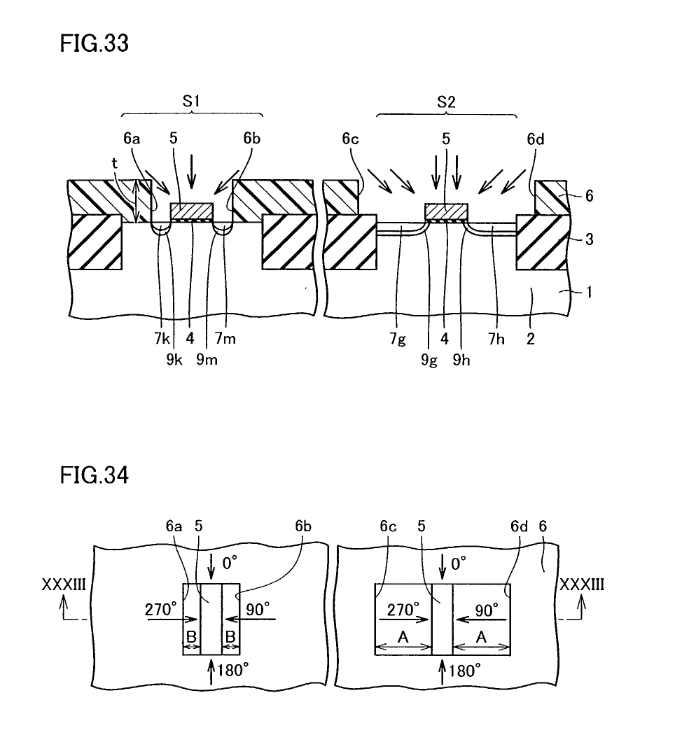

As shown in FIGS. 33 and 34, by using resist pattern 6 formed on semiconductor substrate 1 as a mask, arsenic is implanted into the region of semiconductor substrate 1. At this time, the implantation angle to semiconductor substrate 1 is 45 degrees, implantation energy is 100 KeV, and a dose is 2.3×10¹³/cm². Implantation is carried out by the orientation flat angle 4 step method.

By the implantation, LDD regions 9k and 9m are formed on the surface of element formation region S1 in semiconductor substrate 1, and LDD regions 9g and 9h are formed on the surface of element formation region S2.

As shown in FIG. 34, in resist pattern 6, particularly, in the cases where the orientation flat angle to element formation region S1 is 90 degrees and 270 degrees, distances B each between one side face of gate electrode 5 to an end portion of resist pattern 6 and the film thickness “t” of resist pattern 6 are adjusted so that ions of arsenic are not implanted into the region of semiconductor substrate 1 directly under gate electrode 5.

On the other hand, in resist pattern 6 for element formation region S2, particularly, in the cases where the orientation flat angle is 90 degrees and 270 degrees, distances A each between one side face of gate electrode 5 to an end portion of resist pattern 6 and the film thickness “t” of resist pattern 6 are adjusted so that ions of arsenic are implanted into the region of semiconductor substrate 1 directly under gate electrode 1. After the implantation of arsenic ions, resist pattern 6 is removed.

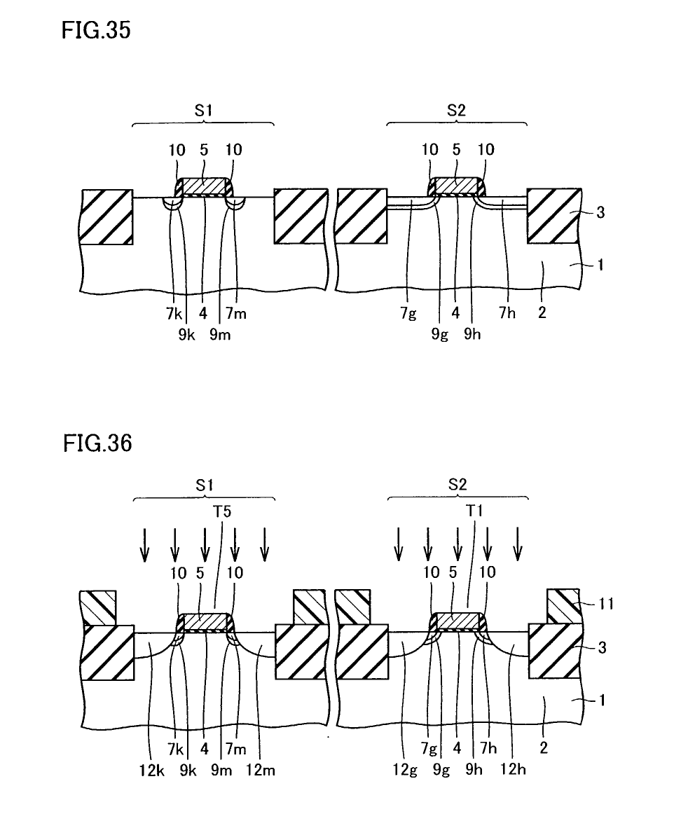

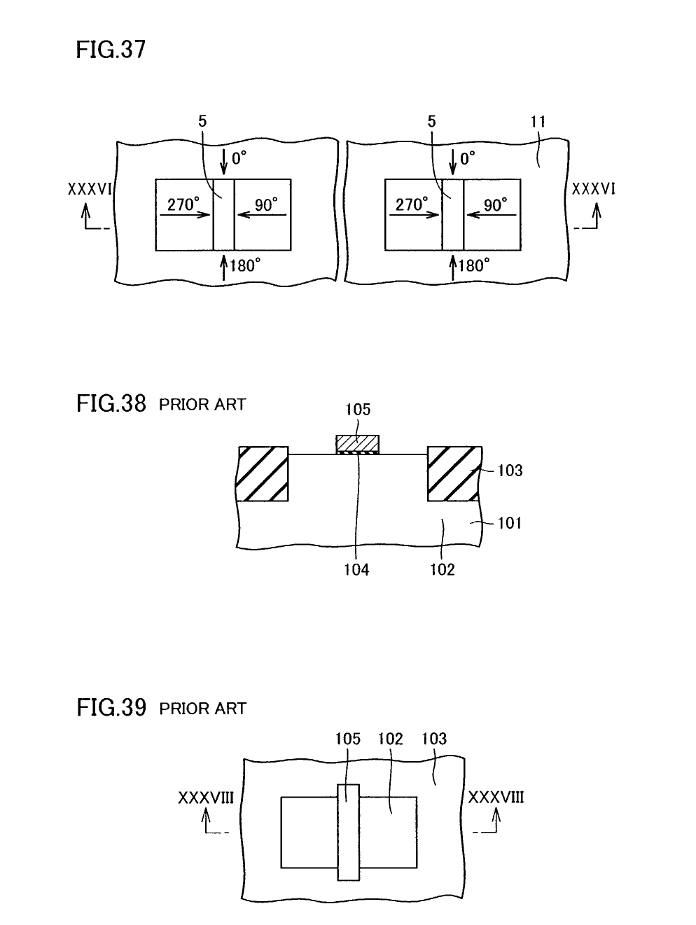

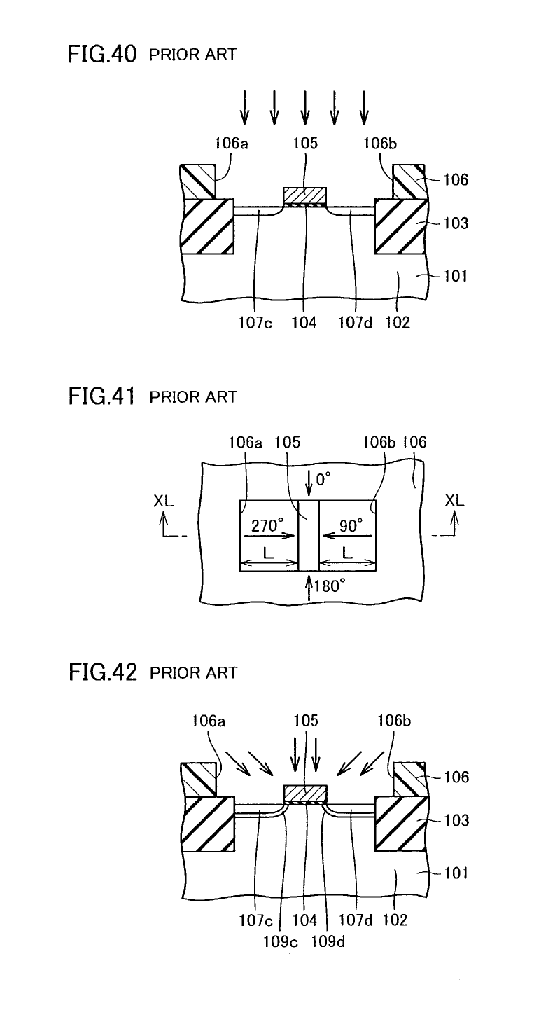

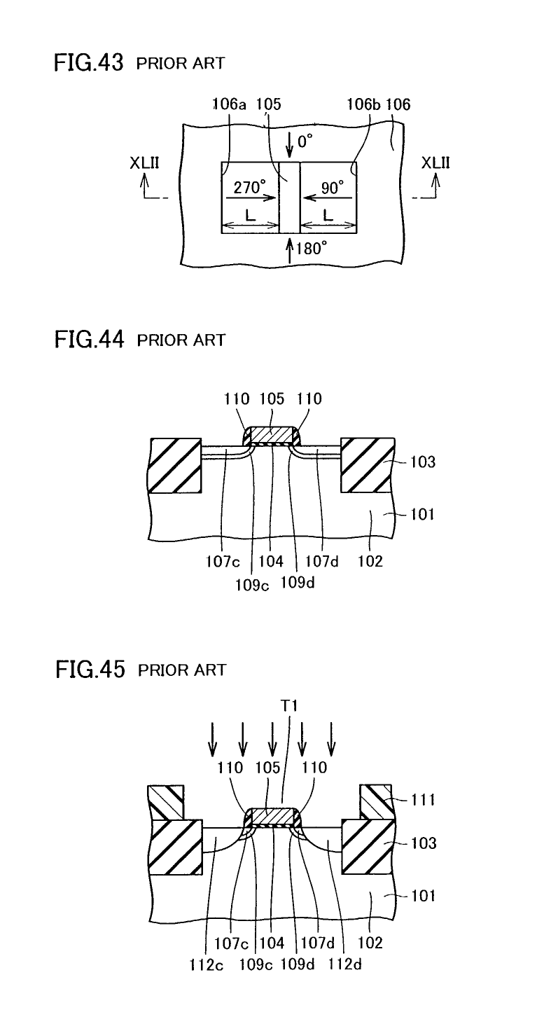

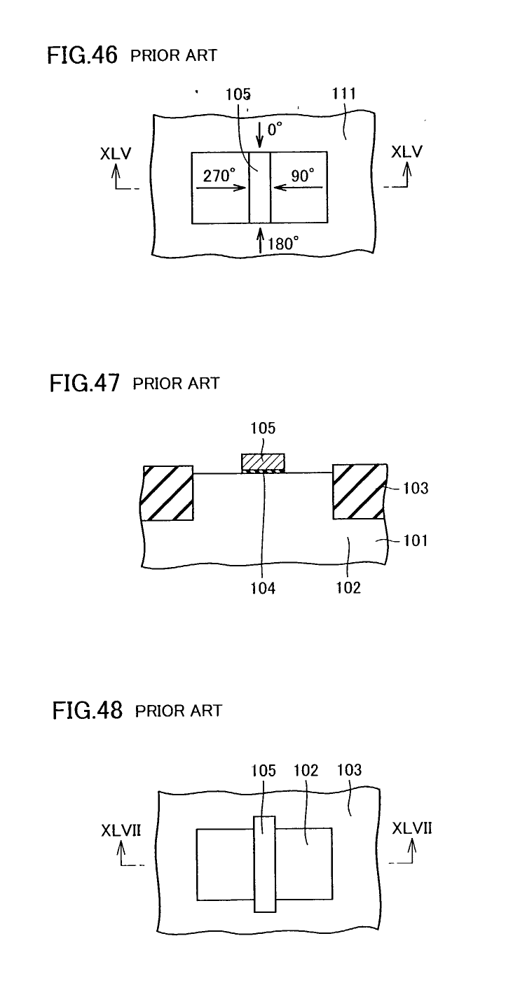

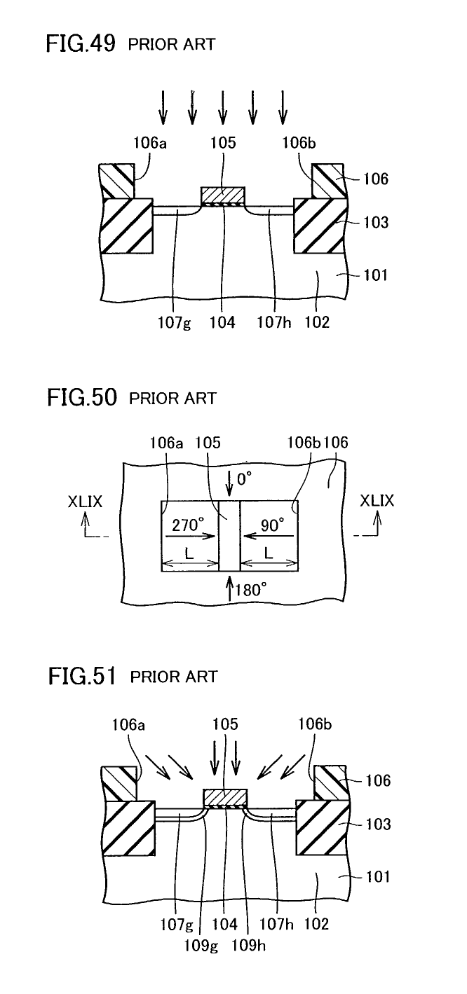

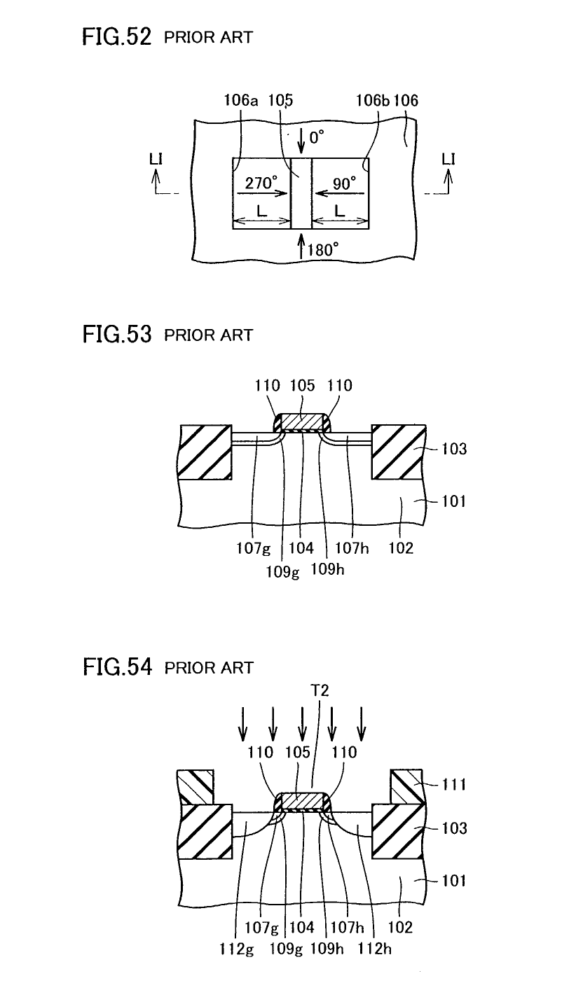

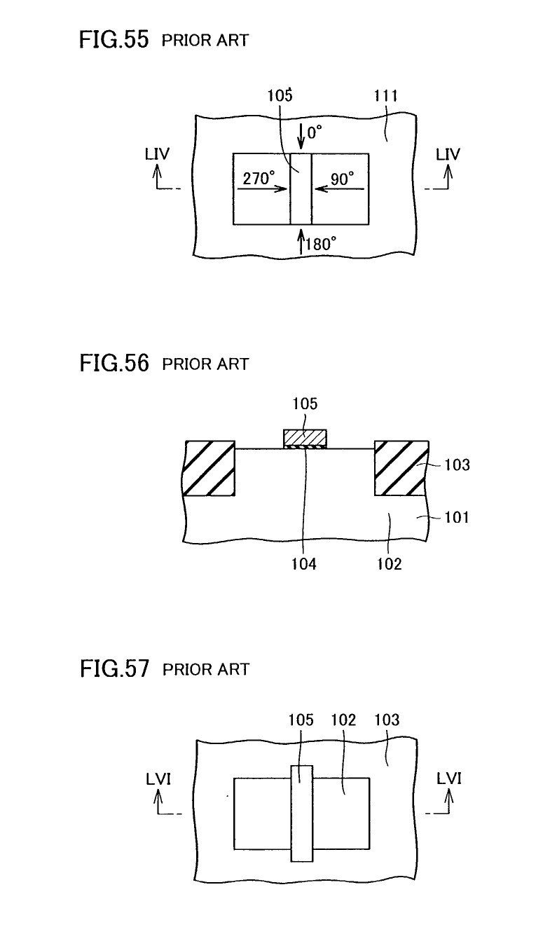

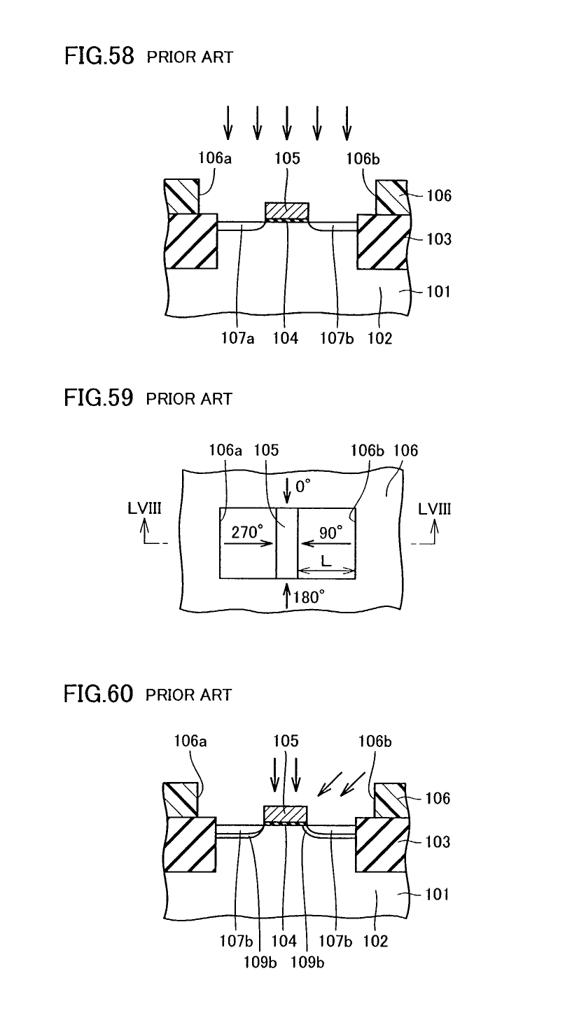

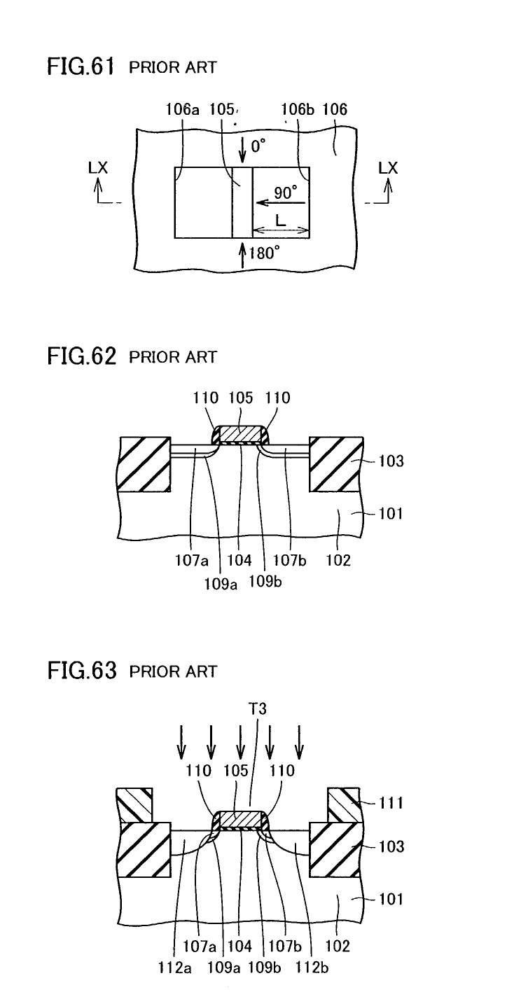

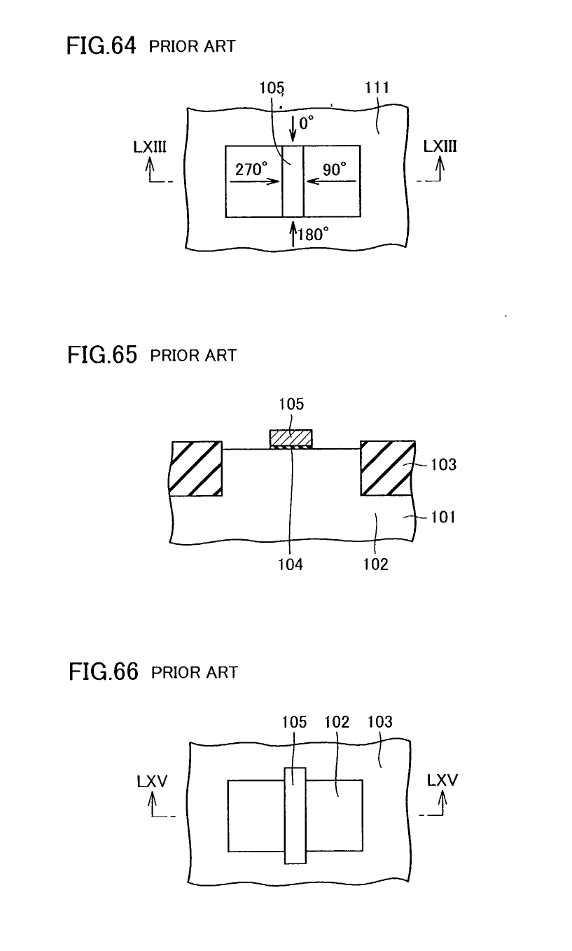

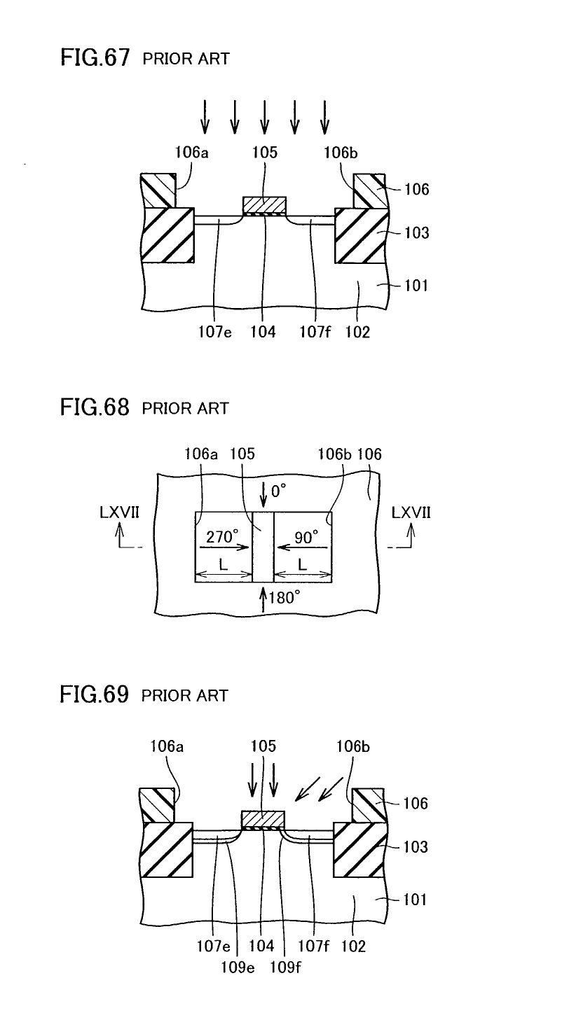

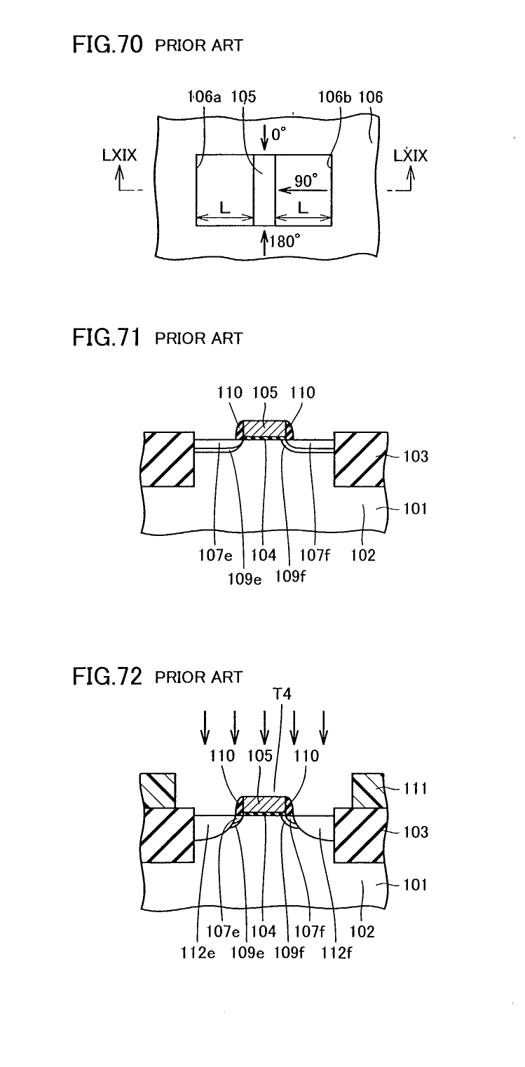

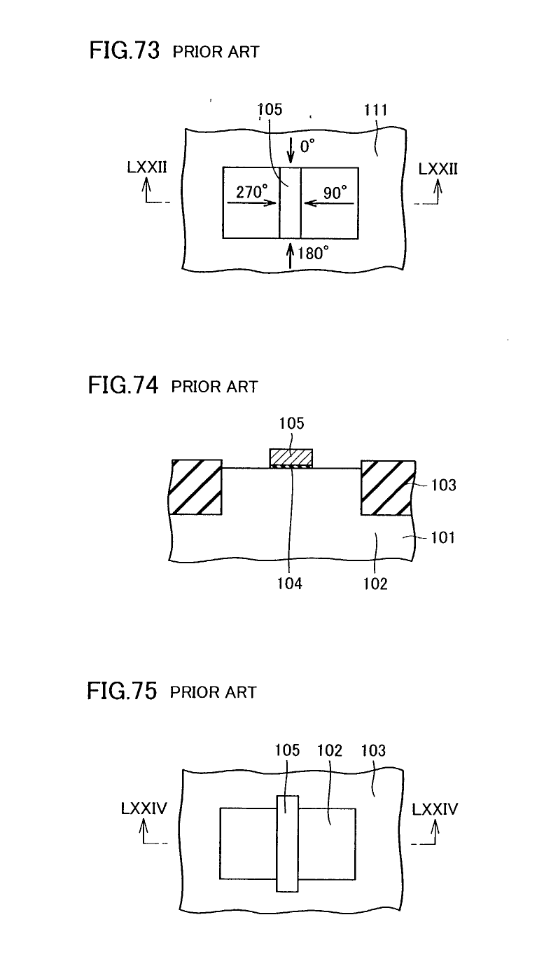

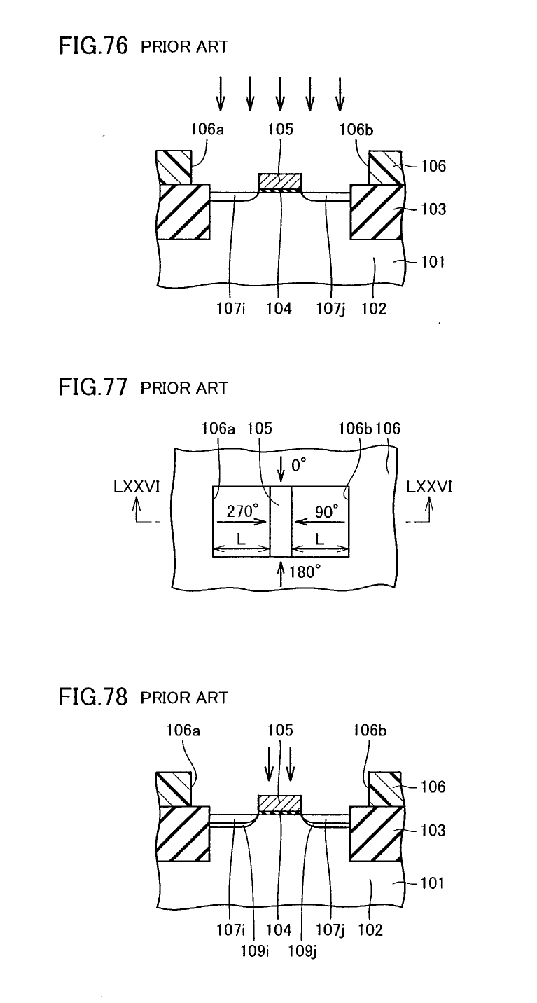

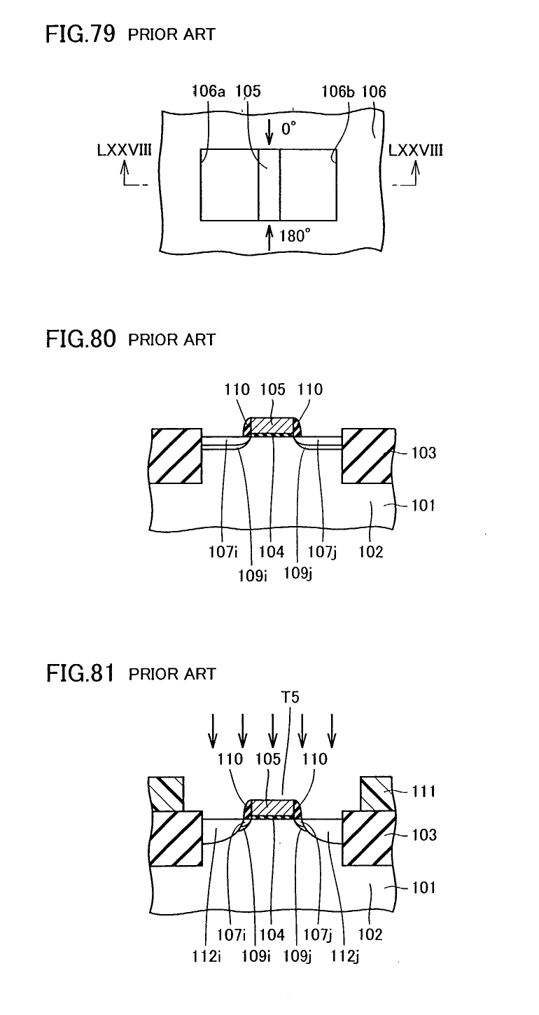

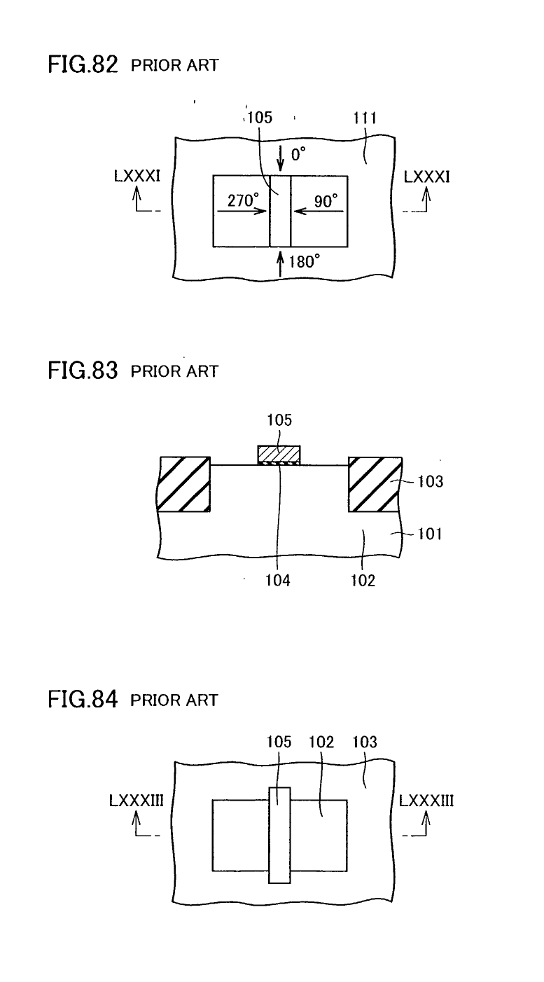

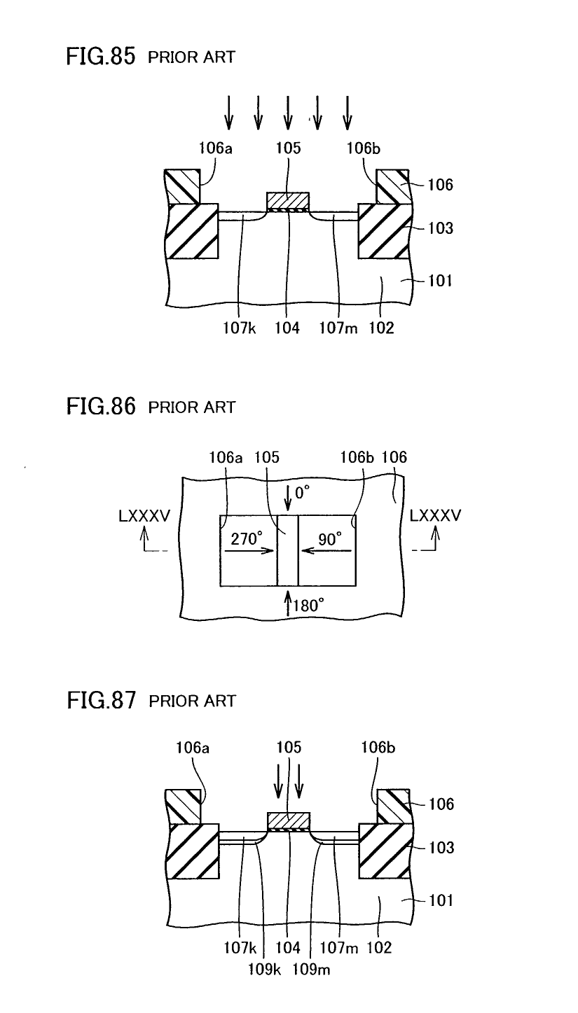

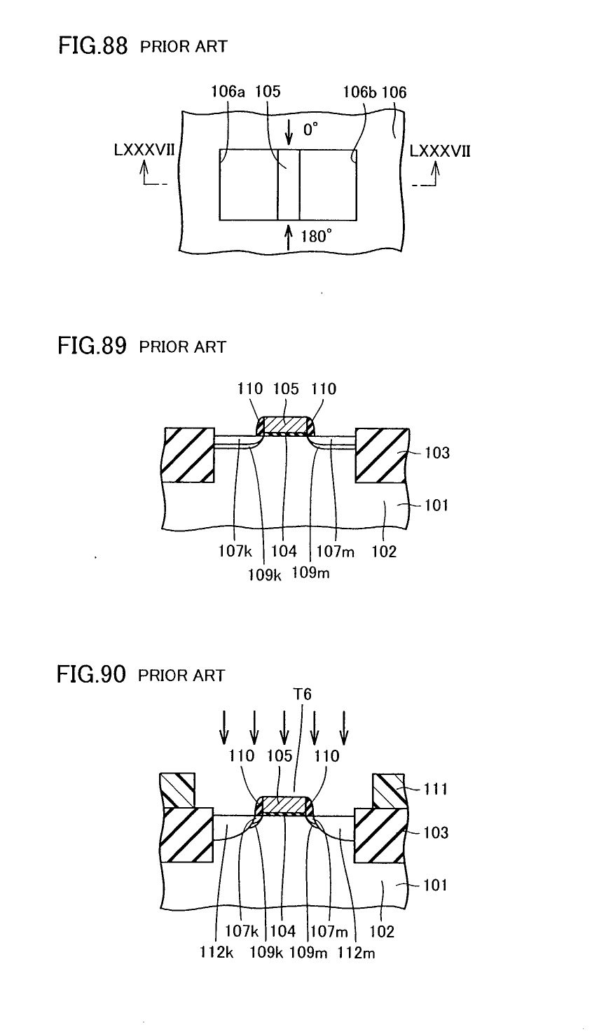

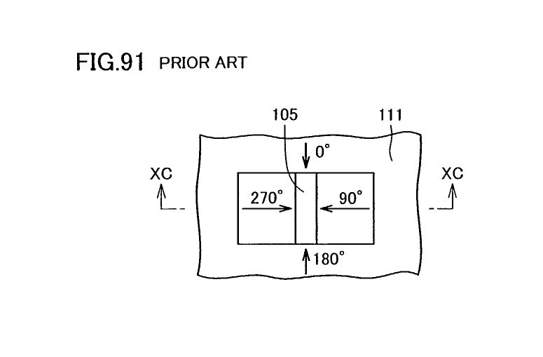

Subsequently, by performing processes similar to the above-described processes, as shown in FIG. 35, side wall insulating film 10 is formed on both side faces of gate electrode 5. As shown in FIGS. 36 and 37, resist pattern 11 is formed on semiconductor substrate 1.

By using resist pattern 11 as a mask, arsenic is implanted into the region of semiconductor substrate 1. At this time, the implantation angle to semiconductor substrate 1 is 0 degrees, implantation energy is 40 KeV, and a dose is 5×10¹⁵/cm². Implantation is performed by the orientation flat angle 4 step method. By the implantation, S/D regions 12k and 12m are formed on the surface of element formation region S1 in semiconductor substrate 1, and S/D regions 12g and 12h are formed on the surface of element formation region S2.

After that, resist pattern 11 is removed, and annealing process and salicide process (which are not shown) are performed, thereby completing a transistor T6 in element formation region S1 and completing a transistor T2 in element formation region S2.

In the method of fabricating the semiconductor device, particularly, in resist pattern 6 used for forming LDD regions shown in FIGS. 33 and 34, distances A and B and film thickness “t” are adjusted so that arsenic ions obliquely implanted into element formation region S1 at a predetermined implantation angle from the side of each of side faces of gate electrode 5 are not implanted into the region of semiconductor substrate 1 positioned directly under gate electrode 5 and, for the other portion, arsenic ions are implanted into the region in semiconductor substrate 1 positioned directly under gate electrode 5.

As compared with the conventional semiconductor device fabricating method, transistors T2 and T6 of different kinds can be simultaneously formed without adding a new process.

Particularly, in transistor T6, by using LDD regions 9k and 9m which do not include the portion formed in the region of semiconductor substrate 1 positioned directly under gate electrode 5 as a drain and a source, the driving capability of the transistor can be improved.

In each of the foregoing embodiments, the case of forming two transistors of different kinds has been described as an example. Except for the above, by adding particularly the pattern for element formation region S1 out of resist patterns 6 used in the processes shown in FIGS. 22 to 25 described in the third embodiment as resist pattern 6 used for the processes shown in FIGS. 3 to 6 described in the first embodiment, three transistors T1, T3, and T5 of different kinds can be simultaneously formed.

By adding particularly the pattern for element formation region S1 out of resist patterns 6 used in the processes shown in FIGS. 31 to 34 described in the fourth embodiment as resist pattern 6 used for the processes shown in FIGS. 13 to 16 described in the second embodiment, three transistors T2, T4, and T6 of different kinds can be simultaneously formed.

Although the n-channel type MOSFET has been described as a transistor in each of the foregoing embodiments, the above-described fabricating method can be also applied to a p-channel type MOSFET.

Further, although the process of forming the SDE and SPI regions in a transistor and the process of forming the SDE and SPI regions have been described as an example, In addition, the present invention can be also applied to a case of forming a first LDD region and a second LDD region of different structures as LDD regions.

Although the case of simultaneously forming two transistors of different kinds has been described in each of the embodiments, each of transistors T1 to T6 can be formed as a single member in element formation region S1 or the like in semiconductor substrate 1 without increasing the number of processes as compared with the conventional method of fabricating transistors T1 to T6.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A method of fabricating a transistor, comprising the steps of:
forming an electrode portion on a main surface of a semiconductor substrate of a first conductive type via an insulating film; and
forming a predetermined impurity region in each of a region in said semiconductor substrate positioned on the side of one of side faces of said electrode portion, and a region in said semiconductor substrate positioned on the side of the other side face of said electrode portion, wherein
the step of forming said electrode portion includes a step of forming a first electrode portion and a second electrode portion, wherein
the step of forming said impurity region includes the steps of:
forming a resist pattern having a predetermined film thickness including a portion for exposing a first surface of said semiconductor substrate from said one of side faces of said first electrode portion to a position apart from said first electrode portion by a first distance and exposing a second surface of said semiconductor substrate from said other side face of said first electrode portion to a position apart from said first electrode portion by a second distance, and a portion for exposing a third surface of said semiconductor substrate from said one of side faces of said second electrode portion to a position apart from said second electrode portion by a third distance and exposing a fourth surface of said semiconductor substrate from said other side face of said second electrode to a position apart from said second electrode by a fourth distance; and
introducing an impurity of a predetermined conductive type by using said resist pattern as a mask, and wherein
in the step of forming said resist pattern,
said predetermined film thickness and at least said first distance are set so as to prevent said impurity of the predetermined conductive type from being obliquely introduced from said one of the side faces into the portion of the region in said semiconductor substrate positioned directly under said first electrode at a predetermined angle with respect to said semiconductor substrate, and
said predetermined film thickness, said third distance, and said fourth distance are set so that said impurity of the predetermined conductive type is introduced obliquely to the portion of the region in said semiconductor substrate positioned directly under said second electrode from said one of side faces and said other side face at said predetermined angle with respect to semiconductor substrate.

2. The method of fabricating the transistor according to claim 1, wherein
in the step of forming said resist pattern,
said predetermined film thickness and said second distance are set so that said impurity of the predetermined conductive type is introduced obliquely into the portion of the region in said semiconductor substrate positioned directly under said first electrode portion from said other side face at said predetermined angle with respect to said semiconductor substrate.

3. The method of fabricating the transistor according to claim 2, wherein
the step of forming said impurity region includes a step of forming a first impurity region of a second conductive type on said first surface, forming a second impurity region of the second conductive type on said second surface, forming a third impurity region of the second conductive type on said third surface, and forming a fourth impurity region of the second conductive type on said fourth surface by introducing an impurity of the second conductive type as said impurity of the predetermined conductive type almost perpendicularly with respect to said semiconductor substrate.

4. The method of fabricating the transistor according to claim 3, wherein
the step of forming said impurity region includes a step of forming a fifth impurity region of the first conductive type on said first surface, forming a sixth impurity region of the first conductive type on said second surface, forming a seventh impurity region of the first conductive type on said third surface, and forming an eighth impurity region of the first conductive type on said fourth surface by introducing an impurity of the first conductive type as said impurity of the predetermined conductive type at said predetermined angle with respect to said semiconductor substrate.

5. The method of fabricating the transistor according to claim 3, wherein
the step of forming said impurity region includes a step of forming a fifth impurity region of the second conductive type on said first surface, forming a sixth impurity region of the second conductive type on said second surface, forming a seventh impurity region of the second conductive type on said third surface, and forming an eighth impurity region of the second conductive type on said fourth surface by introducing an impurity of the second conductive type as said impurity of the predetermined conductive type at said predetermined angle with respect to said semiconductor substrate.

6. The method of fabricating the transistor according to claim 1, wherein
in the step of forming said resist pattern,
said predetermined film thickness and said second distance are set so as to prevent said impurity of the predetermined conductive type from being introduced obliquely into the portion in the region of said semiconductor substrate positioned directly under said first electrode portion from said other side face at said predetermined angle with respect to said semiconductor substrate.

7. The method of fabricating the transistor according to claim 6, wherein
the step of forming said impurity region includes a step of forming a first impurity region of a second conductive type on said first surface, forming a second impurity region of the second conductive type on said second surface, forming a third impurity region of the second conductive type on said third surface, and forming a fourth impurity region of the second conductive type on said fourth surface by introducing an impurity of a second conductive type as said impurity of the predetermined conductive type substantially perpendicular with respect to said semiconductor substrate.

8. The method of fabricating the transistor according to claim 7, wherein
the step of forming said impurity region includes a step of forming a fifth impurity region of the first conductive type on said first surface, forming a sixth impurity region of the first conductive type on said second surface, forming a seventh impurity region of the first conductive type on said third surface, and forming an eighth impurity region of the first conductive type on said fourth surface by introducing an impurity of the first conductive type as said impurity of the predetermined conductive type at said predetermined angle with respect to said semiconductor substrate.

9. The method of fabricating the transistor according to claim 7, wherein
the step of forming said impurity region includes a step of forming a fifth impurity region of the second conductive type on said first surface, forming a sixth impurity region of the second conductive type on said second surface, forming a seventh impurity region of the second conductive type on said third surface, and forming an eighth impurity region of the second conductive type on said fourth surface by introducing an impurity of the second conductive type as said impurity of the predetermined conductive type at said predetermined angle with respect to said semiconductor substrate.

10. The method of fabricating the transistor according to claim 1, wherein
the step of forming said impurity region includes a step of forming a first impurity region of a second conductive type on said first surface, forming a second impurity region of the second conductive type on said second surface, forming a third impurity region of the second conductive type on said third surface, and forming a fourth impurity region of the second conductive type on said fourth surface by introducing an impurity of the second conductive type as said impurity of the predetermined conductive type substantially perpendicular with respect to said semiconductor substrate.

11. The method of fabricating the transistor according to claim 10, wherein
the step of forming said impurity region includes a step of forming a fifth impurity region of the first conductive type on said first surface, forming a sixth impurity region of the first conductive type on said second surface, forming a seventh impurity region of the first conductive type on said third surface, and forming an eighth impurity region of the first conductive type on said fourth surface by introducing an impurity of the first conductive type as said impurity of the predetermined conductive type at said predetermined angle with respect to said semiconductor substrate.

12. The method of fabricating the transistor according to claim 10, wherein
the step of forming said impurity region includes a step of forming a fifth impurity region of the second conductive type on said first surface, forming a sixth impurity region of the second conductive type on said second surface, forming a seventh impurity region of the second conductive type on said third surface, and forming an eighth impurity region of the second conductive type on said fourth surface by introducing an impurity of a second conductive type as said impurity of the predetermined conductive type at said predetermined angle with respect to said semiconductor substrate.
